(19) United States
(12) Patent Application Publication
(10) Pub. No.: US 2025/0374601 A1
(43) Pub. Date: Dec. 4, 2025

(54) Semiconductor Device and Method of Manufacturing the Same

(71) Applicant: Taiwan Semiconductor Manufacturing Company, Ltd., Hsin-Chu (TW)

(72) Inventors: Chang-Ta CHEN, New Taipei City (TW); Ming-Chang WEN, Kaohsiung City (TW); Kuo-Feng YU, Hsinchu County (TW); Che-Hao CHANG, Hsinchu City (TW); Yoh-Rong LIU, Taipei City (TW); Keng-Yao CHEN, Hsinchu (TW); Yun LEE, Taipei County (TW); Chung-Yu LIN, Kaohsiung City (TW)

(21) Appl. No.: 18/934,575

(22) Filed: Nov. 1, 2024

Related U.S. Application Data
(60) Provisional application No. 63/655,198, filed on Jun. 3, 2024.

(51) Int. Cl. H01L 29/417; H01L 21/02; H01L 21/768; H01L 29/06; H01L 29/423; H01L 29/66; H01L 29/775; H01L 29/786

(52) U.S. Cl. CPC H10D 30/6729; H01L 21/02126; H01L 21/02274; H01L 21/76832; H10D 30/014; H10D 30/43; H10D 30/6735; H10D 30/6757; H10D 62/121

(57) ABSTRACT

A method includes forming a tri-layer etch stop layer over a source/drain, for example, by forming a nitrogen-free low-k dielectric layer on the source/drain, forming an oxygen-treated low-k dielectric layer on the nitrogen-free low-k dielectric layer, and forming a dielectric layer on the oxygen-treated low-k dielectric layer. The nitrogen-free dielectric layer has a first dielectric constant, the oxygen-treated low-k dielectric layer has a second dielectric constant that is greater than the first dielectric constant, and the dielectric layer has a third dielectric constant that is greater than the second dielectric constant and the first dielectric constant. The method may further include forming an interlayer dielectric layer over the tri-layer etch stop layer, removing a portion of the tri-layer etch stop layer and a portion of the ILD layer to form a source/drain contact opening that exposes the source/drain, and forming a source/drain contact structure in the source/drain contact opening.

This is a non-provisional application of and claims benefit of U.S. Provisional Patent Application Ser. No. 63/655,198, filed Jun. 3, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component that can be created using a fabrication process) has decreased. This scaling down process generally provides benefits by increasing production efficiency and lowering associated costs. Such scaling down has also increased the complexity of processing and manufacturing ICs, and for these advances to be realized, similar developments in IC materials and manufacturing are needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method, in portion or entirety, for fabricating a source/drain contact structure according to various aspects of the present disclosure.

FIGS. 2-15 are diagrammatic cross-sectional views of a device, in portion or entirety, at various stages of fabricating a source/drain contact structure, such as those associated with the method of FIG. 1, according to various aspects of the present disclosure.

FIG. 16A and FIG. 16B are diagrammatic cross-sectional views of the device, in portion or entirety, of FIG. 15, according to various aspects of the present disclosure.

FIGS. 17-24 are diagrammatic cross-sectional views of different configurations of device 100, in portion or entirety, after fabricating a source/drain contact structure, such as associated with the method of FIG. 1, according to various aspects of the present disclosure.

### DETAILED DESCRIPTION

The present disclosure relates generally to fabricating source/drain contacts, and more particularly, to etch stop layers implemented when fabricating the source/drain contacts.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Etch stop layers (ESLs) (also referred to as contact etch stop layers (CESLs)) are often implemented to protect underlying layers and/or underlying features during semiconductor device fabrication. For example, forming a source/drain contact may include forming an ESL over a source/drain, forming an interlayer dielectric (ILD) layer over the ESL, forming a source/drain contact opening that extends through the ILD layer and the ESL to expose the source/drain, and forming a source/drain contact in the source/drain contact opening. The ESL may protect the source/drain when the ILD layer is etched to form the source/drain contact opening therein. Since the ESL often remains over the source/drain and/or between the source/drain contact and a gate structure (e.g., a gate stack having gate spacers disposed along sidewalls thereof) of a fabricated semiconductor device (e.g., a transistor that includes the source/drain and the gate structure), ESL design, such as ESL composition and ESL fabrication, needs to account for its effect on the fabricated semiconductor device.

The present disclosure provides a tri-layer ESL over a source/drain and method of fabrication thereof that minimizes and/or prevents undesired oxidation of the source/drain during ESL fabrication and/or subsequent fabrication of a semiconductor device. The disclosed tri-layer ESL and method of fabrication thereof is also configured to minimize a dielectric constant of dielectric materials between electrically conductive features of the semiconductor device (e.g., between a source/drain contact and a gate stack thereof and/or between the source/drain and the gate stack), thereby reducing parasitic capacitance therebetween and improving overall device performance (e.g., device speed). Details of the proposed tri-layer etch stop layer over a source/drain and methods of fabrication thereof are described herein. Different embodiments may have different advantages, and no particular advantage is required of any embodiment.

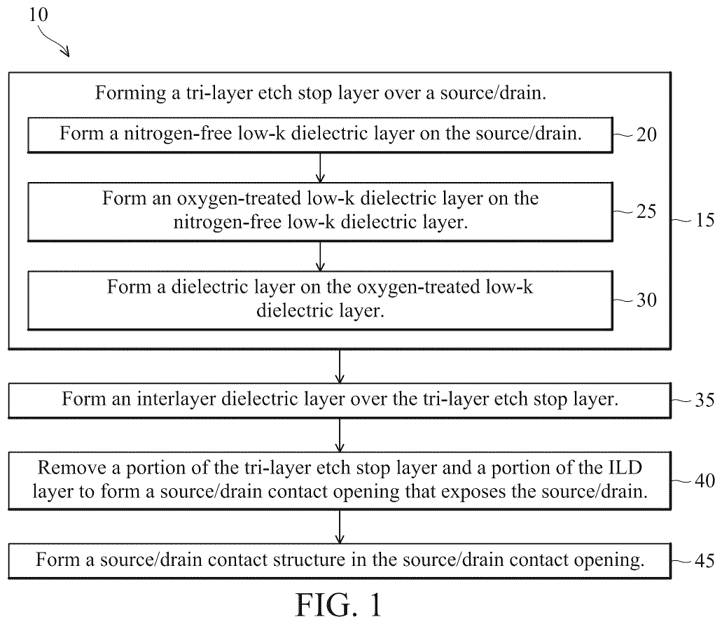

FIG. 1 is a flow chart of a method 10, in portion or entirety, for fabricating a source/drain contact structure according to various aspects of the present disclosure. At block 15, method 10 includes forming a tri-layer ESL over a source/drain. Block 15 may include forming a nitrogen-free low-k dielectric layer (e.g., a silicon oxycarbide layer) on the source/drain at block 20, forming an oxygen-treated low-k dielectric layer (e.g., a silicon oxycarbide layer and/or a silicon oxycarbonitride layer) on the nitrogen-free low-k dielectric layer at block 25, and forming a dielectric layer (e.g., a silicon nitride layer) on the oxygen-treated low-k dielectric layer at block 30. Formation of the nitrogen-free low-k dielectric layer, the oxygen-treated dielectric layer, and the dielectric layer may be configured to provide tri-layer ESL with a dielectric constant that increases from bottom to top thereof and with a nitrogen-free, low dielectric constant portion that interfaces with the source/drain. To prevent source/drain oxidation, the nitrogen-free low-k dielectric layer and the oxygen-treated low-k dielectric layer are formed by respective low temperature, short duration deposition processes. Forming the oxygen-treated low-k dielectric layer may include depositing a low-k dielectric layer on the nitrogen-free low-k dielectric layer and performing an oxygen treatment on the low-k dielectric layer after deposition thereof. To prevent source/drain oxidation, no oxygen treatment is performed between depositing the nitrogen-free low-k dielectric layer and depositing the low-k dielectric layer, and the nitrogen-free low-k dielectric layer and the low-k dielectric layer may be deposited in a same process chamber (e.g., to limit and/or prevent exposure of the nitrogen-free dielectric layer to an oxygen ambient before depositing the low-k dielectric layer, which may occur when transferring a device between process chambers). At block 35, method 10 includes forming an ILD layer over the tri-layer ESL. At block 40, method 10 includes removing a portion of the tri-layer ESL and a portion of the ILD layer to form a source/drain contact opening that exposes the source/drain. At block 45, method 10 includes forming a source/drain contact structure in the source/drain contact opening. Additional steps may be provided before, during, and after method 10, and some of the steps described may be moved, replaced, or eliminated for additional embodiments of method 10. The discussion that follows illustrates devices having source/drain structures fabricated according to method 10.

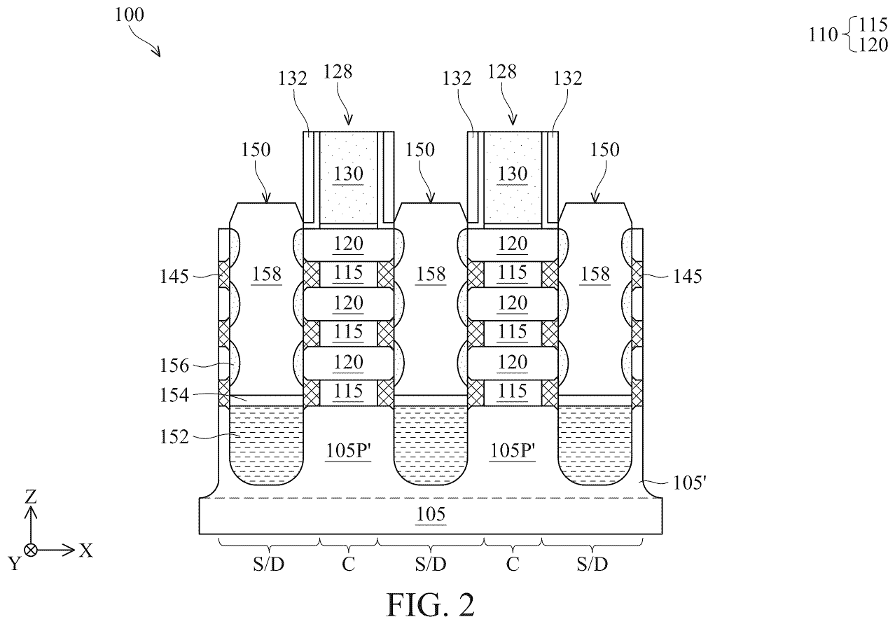

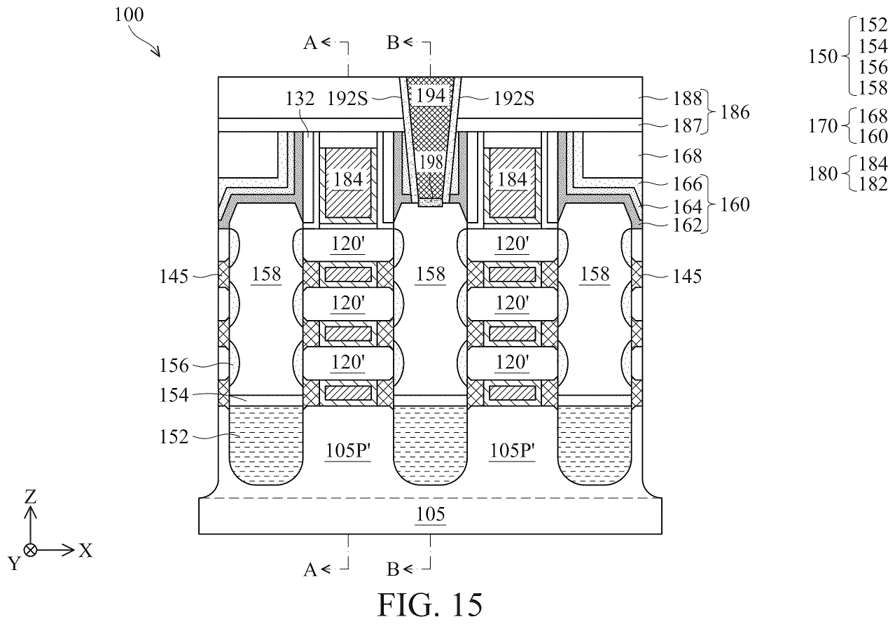

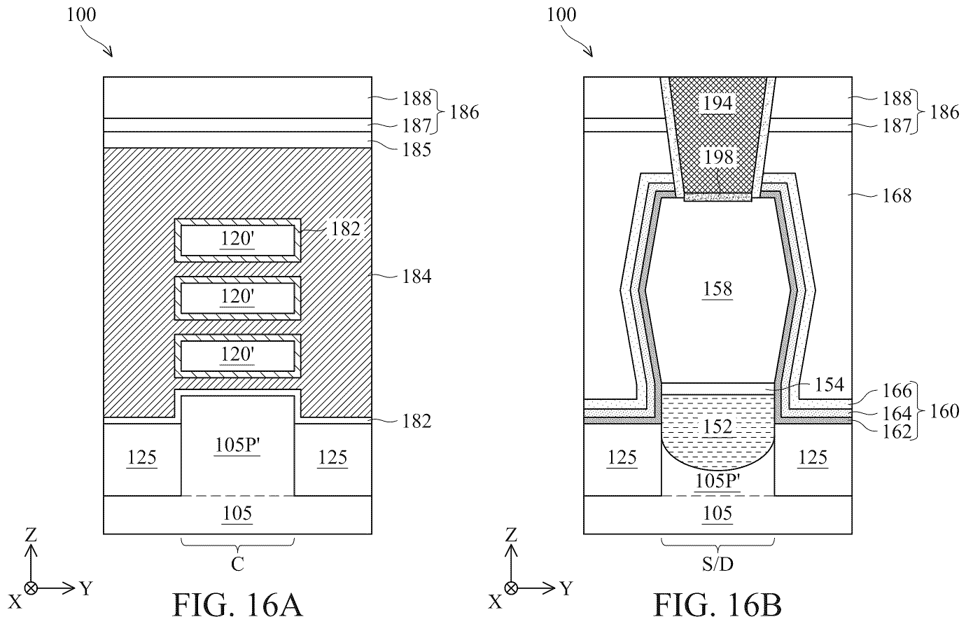

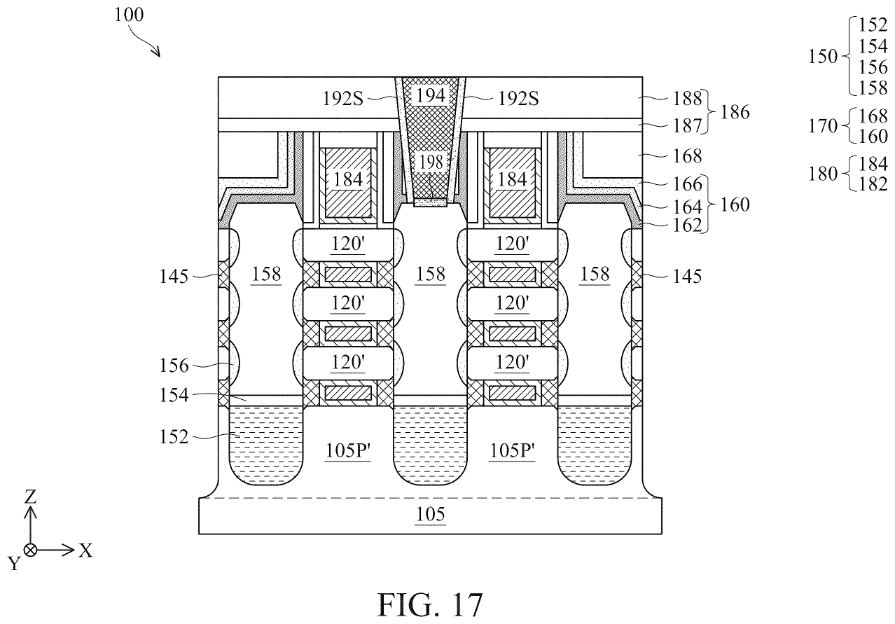

FIGS. 2-15 are diagrammatic cross-sectional views of a device 100, in portion or entirety, at various stages of fabricating a source/drain contact structure (such as those associated with method 10 of FIG. 1) according to various aspects of the present disclosure. FIG. 16A and FIG. 16B are diagrammatic cross-sectional views of device 100, in portion or entirety, along line A-A and line B-B, respectively, of FIG. 15, according to various aspects of the present disclosure. FIGS. 17-24 are diagrammatic cross-sectional views of various embodiments of different configurations of device 100, in portion or entirety, according to various aspects of the present disclosure. Device 100 may include at least one transistor, such as a gate-all-around (GAA) transistor (i.e., a transistor having a gate that at least partially surrounds a suspended channel(s) (for example, a nanowire(s), a nanosheet(s), a nanobar(s), or the like) that extends between source/drains). Device 100 may be included in a microprocessor, a memory, other integrated circuit (IC) device, or combinations thereof. In some embodiments, device 100 is a portion of an IC chip, a system on chip (SoC), or portion thereof, and device 100 may include various passive electronic devices and/or active electronic devices, such as resistors, capacitors, inductors, diodes, p-type field effect transistors (PFETs), n-type FETs (NFETs), metal-oxide-semiconductor FETs (MOSFETs), complementary MOS (CMOS) transistors (including, e.g., an n-type transistor and a p-type transistor), bipolar junction transistors (BJTs), laterally diffused MOS (LDMOS) transistors, high voltage transistors, high frequency transistors, other suitable components, or combinations thereof. FIGS. 2-15, FIG. 16A, FIG. 16B, and FIGS. 17-24 have been simplified for the sake of clarity to better understand the inventive concepts of the present disclosure. Additional features may be added in device 100, and some of the features described below may be replaced, modified, or eliminated in other embodiments of device 100.

Referring to FIG. 2, a device precursor may be formed and/or received for device 100, which may then be processed as described herein to form a source/drain contact structure. Device 100 may include a substrate 105, a mesa 105′, a multilayer stack 110 (including, e.g., mesas 105P′, sacrificial layers 115, and semiconductor layers 120) in channel regions (C) of device 100, substrate isolation structures 125 (see, e.g., FIG. 15A and FIG. 15B), and gate structures 128. In the depicted embodiment, gate structures each include a respective dummy gate stack 130 and respective gate spacers 132. Device 100 may further include inner spacers 145 and source/drain structures 150 disposed in source/drain regions (S/D) of device 100. Each source/drain structure 150 may be multilayered, including, for example, a semiconductor layer 152, an insulator layer 154, a semiconductor layer 156, and a semiconductor layer 158.

Substrate 105 and mesa 105′ (and mesas 105P′) includes an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 105 is a silicon substrate. In some embodiments, substrate 105 is a semiconductor-on-insulator substrate, such as a silicon-on-insulator (SOI) substrate, a silicon germanium-on-insulator (SGOI) substrate, or a germanium-on-insulator (GOI) substrate. Substrate 105 (and mesa 105′) may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, gallium, other p-type dopant, or combinations thereof. In some embodiments, the doped regions include p-type dopants and n-type dopants. The doped regions may be formed on and/or in substrate 105 and/or mesa 105′, for example, providing a p-well structure, an n-well structure, a dual-well structure, a raised structure, other suitable structure, or combinations thereof. In some embodiments, substrate 105 and/or mesa 105′, and semiconductor layers thereover, may include an n-well and/or a p-well. For example, substrate 105, mesa 105′, and/or mesas 105P′ may include a p-well in an n-type transistor region and an n-well in a p-type transistor region.

Sacrificial layers 115 and semiconductor layers 120 are stacked vertically (e.g., along the z-direction) in an interleaving and/or alternating configuration from a top of substrate 105. A composition of sacrificial layers 115 is different than a composition of semiconductor layers 120 to achieve etch selectivity. For example, sacrificial layers 115 and semiconductor layers 120 include different materials, constituent atomic percentages, constituent weight percentages, other characteristics, or combinations thereof to achieve etch selectivity. In some embodiments, sacrificial layers 115 include silicon germanium, semiconductor layers 120 include silicon, and an etch rate of semiconductor layers 120 is different than an etch rate of sacrificial layers 115 to a given etchant. In some embodiments, sacrificial layers 115 and semiconductor layers 120 include the same material but with different constituent atomic percentages. For example, sacrificial layers 115 and semiconductor layers 120 may include silicon germanium but with different germanium atomic percentages. In some embodiments, sacrificial layers 115 are dielectric layers (e.g., sacrificial layers 115 may be oxide layers) and semiconductor layers 120 are silicon layers to provide etch selectivity. Sacrificial layers 115 and semiconductor layers 120 may include any combination of materials that provides desired etching selectivity, desired oxidation rate differences, desired performance characteristics, or combinations thereof (e.g., materials that maximize current flow), including any of the materials disclosed herein.

Semiconductor layers 120 or portions thereof may form channels of transistors of device 100. In FIG. 2, multilayer stack 110 includes three sacrificial layers 115 and three semiconductor layers 120. Multilayer stack 110 thus includes three semiconductor layer pairs disposed over substrate 105, each of which has a respective sacrificial layer 115 and a respective semiconductor layer 120. After processing of multilayer stack 110, this configuration may result in transistors having three channels. However, in some embodiments, multilayer stack 110 includes different numbers of semiconductor layers 120 depending, for example, on a number of channels desired for transistors of and/or design requirements of device 100. For example, multilayer stack 110 may include two to six semiconductor layer pairs, each of which may have a respective sacrificial layer 115 and a respective semiconductor layer 120.

Substrate isolation structures 125 may be formed adjacent to and around a lowerportion of multilayer stack 110 (e.g., mesas 105P′ thereof), and device 100 (e.g., multilayer stacks 110 in channel regions thereof and/or source/drain structures 150 in source/drain regions thereof) may be separated from other devices and/or device regions by substrate isolation structures 125. Substrate isolation structures 125 may electrically isolate an active device region (e.g., mesas 105P′ and/or source/drain structures 150) from other device regions. Substrate isolation structures 125 include silicon oxide, silicon nitride, silicon oxynitride, other suitable isolation material (including, silicon, oxygen, nitrogen, carbon, other suitable isolation constituent, or combinations thereof), or combinations thereof. Substrate isolation structures 125 may have a multilayer structure. For example, substrate isolation structures 125 may include a bulk dielectric (e.g., an oxide layer) over a dielectric liner (e.g., silicon nitride, silicon oxide, silicon oxynitride, silicon oxycarbonitride, or combinations thereof). In another example, substrate isolation structures 125 may include a bulk dielectric over a doped liner, such as a boron silicate glass (BSG) liner and/or a phosphosilicate glass (PSG) liner. Dimensions and/or characteristics of substrate isolation structures 125 may be configured to provide shallow trench isolation (STI) structures, deep trench isolation (DTI) structures, local oxidation of silicon (LOCOS) structures, other suitable isolation structures, or combinations thereof.

Gate structures 128 may be formed over channel regions (C) of device 100 (e.g., multilayer stack 110) and between respective source/drain regions (S/D) of device 100 (e.g., source/drain structures 150). As noted, gate structures 128 may include a respective dummy gate stack 130 and respective gate spacers 132. Dummy gate stacks 130 extend lengthwise along a direction different than (e.g., orthogonal to) the lengthwise direction of multilayer stack 110. For example, dummy gate stacks 130 extend along the y-direction, having a length along the y-direction, a width along the x-direction, and a height along the z-direction. Dummy gate stacks 130 may extend substantially parallel to one another. In FIG. 2 (e.g., the X-Z plane), dummy gate stacks 130 are disposed on top of respective channel regions of device 100, and dummy gate stacks 130 are disposed between respective source/drain regions of device 100. In a cross-sectional view along a Y-Z plane, dummy gate stacks 130 may wrap respective channel regions (e.g., be disposed over the top and sidewalls thereof), and dummy gate stacks 130 may be disposed over tops of substrate isolation structures 125, in some embodiments.

Dummy gate stacks 130 may include a dummy gate dielectric and a dummy gate electrode. The dummy gate dielectric includes a dielectric material, such as silicon oxide and/or other suitable dielectric material. The dummy gate electrode includes a suitable dummy gate material, such as polysilicon. Dummy gate stacks 130 may further include a hard mask, which may be configured to protect the dummy gate dielectric and/or the dummy gate electrode during processing. For example, the hard mask may include a material that is resistant to an etching process, such as etching associated with forming source/drain recesses and/or etching associated with forming source/drain contact openings, to protect the dummy gate dielectric and/or the dummy gate electrode therefrom. In some embodiments, the hard mask has a multilayer structure. The hard mask includes any suitable hard mask material.

Gate spacers 132 are formed adjacent to and along sidewalls of dummy gate stacks 130. Gate spacers 132 include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). In some embodiments, gate spacers 132 have a multilayer structure, such as two or more dielectric layers having different compositions. In some embodiments, gate spacers 132 include more than one set of spacers, such as seal spacers, offset spacers, sacrificial spacers, dummy spacers, main spacers, or combinations thereof. In such embodiments, the various sets of spacers may have different compositions.

Inner spacers 145 are disposed under gate structures 128 (e.g., under gate spacers 132 thereof) and along sidewalls of sacrificial layers 115. Inner spacers 145 are disposed between sacrificial layers 115 and source/drain structures 150, between adjacent semiconductor layers 120, and between bottommost semiconductor layer 120 and mesas 105P′. Inner spacers 145 include a dielectric material that includes silicon, oxygen, carbon, nitrogen, or combinations thereof, such as silicon oxide, silicon nitride, silicon oxynitride, silicon carbide, silicon oxycarbonitride, etc. In some embodiments, inner spacers 145 include a low-k dielectric material. In some embodiments, dopants (e.g., p-type and/or n-type) are introduced into the dielectric material, and inner spacers 145 include doped dielectric material(s).

Source/drain structures 150 include a semiconductor material, source/drain structures 150 may be doped with n-type dopants and/or p-type dopants, and source/drain structures 150 may have the same or different compositions and/or materials. In some embodiments, the semiconductor material(s) of source/drain structures 150 are formed by an epitaxy process, and source/drain structures 150 are formed of epitaxially grown/deposited semiconductor material. In such embodiments, source/drain structures 150 may be referred to as epitaxial source/drains. In some embodiments (e.g., when forming portions of n-type transistors), source/drain structures 150 may include silicon doped with carbon, phosphorous, arsenic, other n-type dopant, or combinations thereof. In some embodiments (e.g., when forming portions of p-type transistors), source/drain structures 150 may include silicon germanium or germanium doped with boron, other p-type dopant, or combinations thereof. In some embodiments, doped regions, such as heavily doped source/drain (HDD) regions, lightly doped source/drain (LDD) regions, other doped regions, or combinations thereof, are disposed in source/drain structures 150. In some embodiments, the doped regions, such as LDD regions, may extend into channel regions. As used herein, source/drain region, source/drain, source/drain structure, epitaxial source/drain, epitaxial source/drain feature, etc. may refer to a source of device 100, a drain of device 100, a source and a drain collectively of device 100 or a source and/or a drain of multiple devices.

Each source/drain structure 150 may include a respective semiconductor layer 152, a respective insulator layer 154, a respective semiconductor layer 156, and a respective semiconductor layer 158. Semiconductor layers 152 are disposed on mesas 105P′ and/or substrate 105. In the depicted embodiment, semiconductor layers 152 include dopant-free semiconductor material (i.e., substantially free of n-type and p-type dopants). For example, no intentional doping is performed when forming semiconductor layers 152, e.g., by an epitaxial growth process. Semiconductor layers 152 may thus provide high resistance paths at bottoms of source/drain structures 150, thereby hindering leakage current from flowing between source/drain structures 150 through mesas 105P′ and/or substrate 105. In some embodiments, the undoped semiconductor layers are formed of include silicon, germanium, silicon germanium, other suitable semiconductor materials, or combinations thereof. For example, semiconductor layers 152 may be dopant-free silicon or dopant-free silicon germanium layers.

Insulator layers 154 are disposed on semiconductor layers 152, and insulator layers 154 may be disposed between semiconductor layers 158 and semiconductor layers 152. Insulator layers 154 include an electrically insulating material, such as a dielectric material, that may also hinder unwanted leakage current from flowing between source/drain structures 150 (e.g., semiconductor layers 158 thereof) through mesas 105P′ and/or substrate 105. In some embodiments, insulator layers 154 include a silicon-comprising dielectric material, such as silicon nitride, silicon oxynitride, silicon oxycarbonitride, silicon oxycarbide, silicon carbonitride, other silicon-comprising dielectric material (which may include silicon and nitrogen, carbon, oxygen, other suitable dielectric constituent, or combinations thereof), or combinations thereof. In some embodiments, insulator layers 154 include a metal-comprising dielectric material, such as a metal oxide material (e.g., aluminum oxide and/or hafnium oxide) and/or a metal nitride material. In some embodiments, insulator layers 154 include a doped semiconductor material that includes an opposite type of dopant than semiconductor layers 158. For example, where source/drain structures 150 are portions of p-type transistors having p-type doped semiconductor layers, insulator layers 154 may include an n-type doped semiconductor material, such as phosphorous-doped silicon. In another example, where source/drain structures 150 are portions of n-type transistors having n-type doped semiconductor layers, insulator layers 154 may include p-doped semiconductor material, such as boron-doped silicon.

Semiconductor layers 156 and semiconductor layers 158 are disposed over insulator layers 154 and are coupled to semiconductor layers 120. Semiconductor layers 156 may be disposed between semiconductor layers 158 and semiconductor layers 120. In the depicted embodiment, semiconductor layers 156 and semiconductor layers 158 include a semiconductor material (e.g., silicon, germanium, silicon germanium, other suitable semiconductor materials, or combinations thereof) that is doped with n-type dopants and/or p-type dopants. Semiconductor layers 156 and semiconductor layers 158 may have different compositions and/or different dimensions/configurations, and the different compositions may be achieved with different semiconductor materials, different dopants, different constituent atomic percentages, different dopant concentrations, or combinations thereof. For example, semiconductor layers 158 may be heavily doped semiconductor layers, and semiconductor layers 156 may be lightly doped semiconductor layers, where a dopant concentration of the heavily doped semiconductor layers is greater than a dopant concentration of the lightly doped semiconductor layers. In some embodiments, semiconductor layers 156 and semiconductor layers 158 may include silicon doped with different concentrations of carbon, phosphorous, arsenic, antimony, other n-type dopant, or combinations thereof. In another example, semiconductor layers 156 and semiconductor layers 158 may include silicon germanium doped with different concentrations of boron, gallium, other p-type dopant, or combinations thereof. In some embodiments, semiconductor layers 156 and semiconductor layers 158 include materials and/or dopants that provide desired tensile stress and/or compressive stress in the channel regions.

Before forming source/drain structures 150, multilayer stack 110 (e.g., mesa 105′, sacrificial layers 115, and semiconductor layers 120 thereof) may extend continuously and substantially along an x-direction, having a length along the x-direction, a width along a y-direction, and a height along a z-direction. Multilayer stack 110 may be referred to as a fin, a fin structure, a fin element, an active fin region, an active region, etc. In some embodiments, mesa 105′ is a patterned, projecting portion and/or extension of substrate 105, and mesa 105′ may be referred to as a substrate extension, a substrate fin portion, a fin portion, an etched substrate portion, etc. While forming source/drain structures 150, sacrificial layers 115, semiconductor layers 120, and mesa 105′ (in some embodiments) may be removed to form source/drain recesses in source/drain regions of device 100, in which source/drain structures 150 are formed. After forming the source/drain recesses, which may extend into mesa 105′, portions of multilayer stack 110 may remain in the channel regions of device 100, and such portions may include mesas 105P′, sacrificial layers 115, and semiconductor layers 120, as depicted.

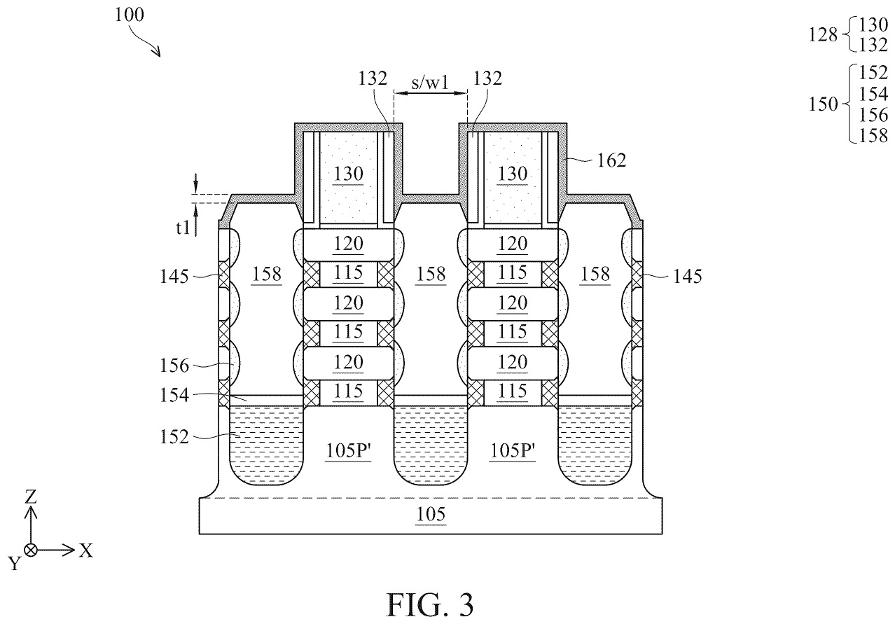

Referring to FIGS. 3-6, a tri-layer etch stop layer (ESL) 160 is formed over device 100, such as over source/drain structures 150 thereof. Tri-layer ESL 160 is configured with a combination of dielectric layers and fabricated in a manner that reduces and/or prevents undesired oxidation of source/drain structures 150 during formation of tri-layer ESL 160 and/or during subsequent processing of device 100. Tri-layer ESL 160 and method of formation thereof is also configured to minimize a dielectric constant of dielectric material between a subsequently formed source/drain contact and gate stacks of gate structures 128 and/or between source/drain structures 150 and gate stacks of gate structures 128, which reduce parasitic capacitance. As described herein, tri-layer ESL 160 includes a nitrogen-free low-k dielectric layer 162, an oxygen-treated low-k dielectric layer 164, and a dielectric layer 166.

Referring to FIG. 3, nitrogen-free low-k dielectric (NFD) layer 162 is formed over device 100, such as over gate structures 128 and source/drain structures 150. In the depicted embodiment, NFD layer 162 is formed directly on gate structures 128 and source/drain structures 150. NFD layer 162 has a thickness t1. Thickness t1 is less than a spacing between adjacent gate structures 128 (e.g., a distance s between gate spacers 132 thereof), such that NFD layer 162 partially fills the spacing (and/or distance s). The spacing (and/or distance s) may be about the same as a width w1 of a top of a respective source/drain structure 150 between the adjacent gate structures 128. In some embodiments, thickness t1 is about 0.5 nm to about 1.5 nm.

NFD layer 162 is formed of a low-k dielectric material that is free of nitrogen. For purposes of the present disclosure, low-k dielectric material generally refers to a dielectric material having a dielectric constant that is less than a dielectric constant of silicon dioxide (k≈3.9), and NFD layer 162 is formed of a nitrogen-free dielectric material having a dielectric constant that is less than about 3.9. In some embodiments, NFD layer 162 is formed of a dielectric material having a dielectric constant that is at least 3.6 (i.e., 3.6≤k<3.9). In some embodiments, NFD layer 162 includes silicon, oxygen, and carbon. For example, NFD layer 162 is a silicon oxycarbide (SiOC) layer having a dielectric constant of about 3.6 to about 3.7 (i.e., 3.6≤k≤3.7). In some embodiments, NFD layer 162 has a silicon content (Si %) of about 25 atomic percent (at %) to about 35 at %, a carbon content (C %) of about 20 at % to about 30 at %, an oxygen content (O %) of about 40 at % to about 50 at %, and a nitrogen content (N %) that is less than about 1 at %. For purposes of the present disclosure, low-k dielectric materials having a nitrogen content (N %) that is less than about 1 at % are considered nitrogen-free. In other words, nitrogen is not intentionally incorporated into NFD layer 162 during formation thereof (e.g., during deposition), but trace/negligible amounts of nitrogen (i.e., N % less than about 1 at %) may unintentionally be incorporated into and/or diffuse into NFD layer 162 during fabrication of device 100. Nitrogen content greater than 1 at % may undesirably provide NFD layer 162 with a dielectric constant that is greater than or equal to 3.9, thereby undesirably increasing an effective dielectric constant of tri-layer ESL 160 and negating parasitic capacitance reductions achieved by providing NFD layer 162 with a dielectric constant less than 3.9.

Since NFD layer 162 is formed directly on and interfaces with source/drain structures 150, oxygen contained in NFD layer 162 may undesirably react with source/drain structures 150 (e.g., with silicon and/or germanium contained therein) during formation of NFD layer 162 and/or during subsequent processing of device 100, thereby undesirably oxidizing source/drain structures 150. The present disclosure recognizes that such undesirable reactions and oxidation occur more readily when higher thermal budgets (i.e., temperatures greater than or equal to 600° C.) are implemented when forming an ESL over a source/drain. Accordingly, the present disclosure forms NFD layer 162 using a low temperature, short duration deposition process (e.g., one that implements a deposition temperature that is less than about 600° C. and a deposition time that is less than about one hour). For example, NFD layer 162 is formed by plasma enhanced chemical vapor deposition (PECVD), which enables low temperature, short duration deposition, such as a deposition temperature that is less than about 600° C. and a deposition time that is less than about one hour. In some embodiments, the PECVD deposition temperature is about 200° C. to about 600° C. In some embodiments, the PECVD deposition time is about 6 minutes (0.1 hours) to about 1 hour. Higher deposition temperatures, such as those greater than 600° C., and/or longer deposition times, such as those greater than one hour, may result in undesired source/drain oxidation. For example, deposition temperatures greater than 600° C. may trigger reactions between oxygen (such as that in NFD layer 162) and source/drain structures 150 and/or increase a reaction rate between oxygen and source/drain structures 150, and deposition times greater than one hour may enable reactions to occur between oxygen (such as that in NFD layer 162) and source/drain structures 150, thereby resulting in unwanted source/drain oxidation. The proposed low temperature, short duration deposition of NFD layer 162 thus reduces reactions between oxygen and source/drain structures 150, thereby reducing source/drain oxidation. In some embodiments, the PECVD generates a plasma that contains at least silicon, oxygen, and carbon. In some embodiments, the plasma further contains hydrogen. The plasma may be generated by flowing a deposition precursor gas(es) that includes silicon, carbon, oxygen, or combinations thereof (e.g., trimethylsilane, methyltriethoxysilane, oxygen (O₂), other precursors, or combinations thereof) and a carrier gas (e.g., an inert gas) into a process chamber and generating a silicon-carbon-and-oxygen-containing plasma therefrom using radio frequency (RF) power and/or direct current (DC) power. PECVD parameters (e.g., deposition temperature, deposition time, deposition gas(es), pressure, power, bias, etc.) may be tuned to minimize source/drain oxidation, provide NFD layer 162 with a dielectric constant less than about 3.9, provide NFD layer 162 with an oxygen content less than about 50 at %, or combinations thereof.

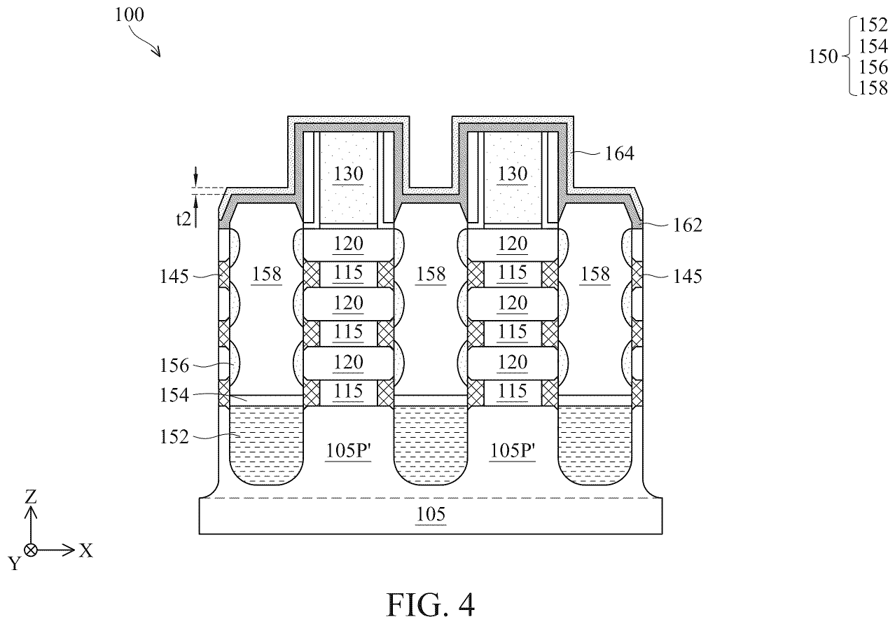

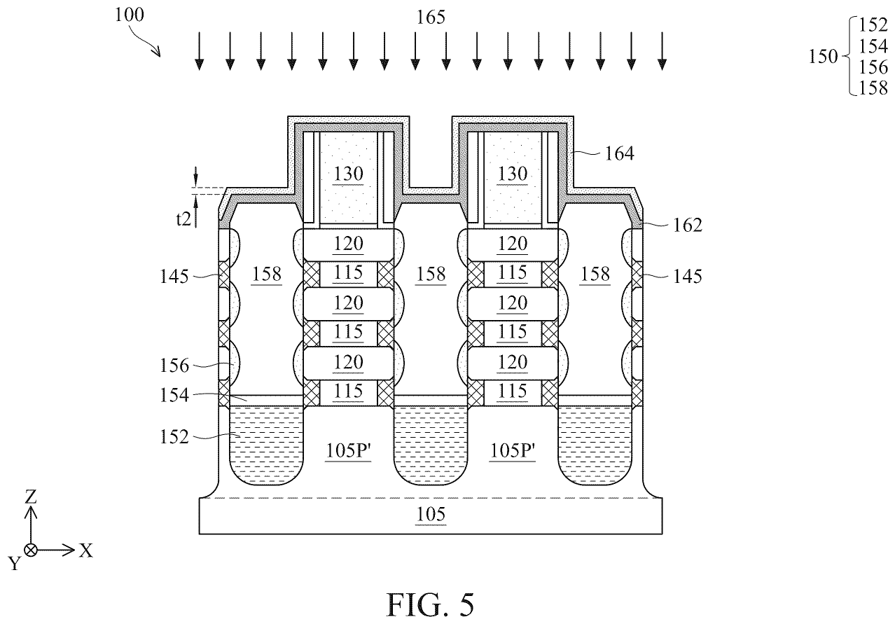

Referring to FIG. 4 and FIG. 5, a low-k dielectric (LKD) layer 164′ is formed over NFD layer 162 (FIG. 4), and an oxygen treatment 165 is performed on LKD layer 164′ (FIG. 5), thereby forming oxygen-treated LKD layer 164. In the depicted embodiment, oxygen-treated LKD layer 164 is formed directly on NFD layer 162. LKD layer 164′ and oxygen-treated LKD layer 164 has a thickness t2. Thickness t2 is less than the spacing between the adjacent gate structures 128, such that oxygen-treated LKD layer 164 also partially fills the spacing (and/or distance s) therebetween. A sum of thickness t2 and thickness t1 is less than the spacing between the adjacent gate structures 128. Thickness t2 may be the same as, greater than, or less than thickness t1. In some embodiments, thickness t2 is about 0.5 nm to about 1.5 nm.

Oxygen-treated LKD layer 164 is formed of a low-k dielectric material, which may or may not be free of nitrogen. In the depicted embodiment, oxygen-treated LKD layer 164 is formed of a dielectric material having a dielectric constant that is greater than the dielectric constant of the dielectric material of NFD layer 162. In other words, a dielectric constant of oxygen-treated LKD layer 164 is greater than a dielectric constant of NFD layer 162. In some embodiments, oxygen-treated LKD layer 164 is formed of a dielectric material having a dielectric constant that is less than about 3.9, such as a dielectric constant that is about 3.6 to about 3.9 (i.e., 3.6≤k<3.9). In such embodiments, oxygen-treated LKD layer 164 may be a nitrogen-free layer. For example, oxygen-treated LKD layer 164 includes silicon, oxygen, and carbon, and oxygen-treated LKD layer 164 is a silicon oxycarbide (SiOC) layer. In such embodiments, an oxygen content of oxygen-treated LKD layer 164 is greater than an oxygen content of NFD layer 162. In some embodiments, a carbon content of oxygen-treated LKD layer 164 is different than (e.g., less than) a carbon content of NFD layer 162. In some embodiments, oxygen-treated LKD layer 164 has a silicon content (Si %) of about 25 at % to about 35 at %, a carbon content (C %) of about 5 at % to about 15 at %, and an oxygen content (O %) of about 55 at % to about 70 at %. In such embodiments, oxygen-treated LKD layer 164 may have a nitrogen content that is less than about 1 at %. In some embodiments, oxygen-treated LKD layer 164 includes nitrogen (i.e., oxygen-treated LKD layer 164 has a nitrogen content that is greater than 1 at %). For example, oxygen-treated LKD layer 164 includes silicon, nitrogen, oxygen, and carbon. In such example, oxygen-treated LKD layer 164 may be a silicon oxycarbonitride (SiOCN) layer having a dielectric constant that is greater than 3.9 (e.g., k≈4.3).

Referring to FIG. 4, to minimize source/drain oxidation, LKD layer 164′ is also formed by a low temperature, short duration deposition process (e.g., one that implements a deposition temperature that is less than about 600° C. and a deposition time that is less than about one hour). For example, LKD layer 164′ is also formed by PECVD, which enables low temperature, short duration deposition. In some embodiments, the PECVD deposition temperature is about 200° C. to about 600° C. In some embodiments, the PECVD deposition time is about 6 minutes to about 1 hour. Higher deposition temperatures, such as those greater than 600° C., and/or longer deposition times, such as those greater than one hour, for LKD layer 164′ may result in undesired source/drain oxidation. The low temperature, short duration deposition of LKD layer 164′ thus reduces and/or prevents reactions between oxygen and source/drain structures 150, thereby reducing and/or preventing source/drain oxidation. In some embodiments, the PECVD generates a plasma that contains at least silicon, oxygen, and carbon. In some embodiments, the plasma further contains nitrogen and/or hydrogen. The plasma may be generated by flowing a deposition precursor gas(es) that includes silicon, carbon, oxygen, nitrogen, or combinations thereof (e.g., trimethylsilane, methyltriethoxysilane, oxygen (O₂), other precursors, or combinations thereof) and a carrier gas (e.g., an inert gas) into a process chamber and generating a silicon-carbon-and-oxygen-containing plasma therefrom using RF power and/or DC power. Parameters of the PECVD (e.g., deposition temperature, deposition time, deposition gas(es), pressure, power, bias, etc.) are tuned to minimize source/drain oxidation, provide LKD layer 164′ with a dielectric constant that is greater than a dielectric constant of NFD layer 162, provide LKD layer 164′ with a desired oxygen content, or combinations thereof. In some embodiments, LKD layer 164′, as deposited, has an oxygen content that is less an oxygen content of oxygen-treated LKD layer 164′. In some embodiments, the oxygen content of LKD layer 164′ is less than about 50 at %. In some embodiments, LKD layer 164′ has the same oxygen content as NFD layer 162. For example, LKD layer 164′ may have an oxygen content that is about 40 at % to about 50 at %.

Sometimes, during processing, exposed surfaces of device 100 may be altered when exposed to external ambient as device 100 is transferred between process systems and/or process chambers, such as from one deposition chamber to another deposition chamber. For example, oxygen may diffuse into and/or react with NFD layer 162 when exposed to oxygen ambient, which may unintentionally increase an oxygen content of NFD layer 162 (e.g., to greater than 50 at %, in some embodiments), which as described herein, may exacerbate undesired source/drain oxidation that degrades performance of device 100. Accordingly, to minimize and/or prevent oxidation of NFD layer 162, which may lead to unintended source/drain oxidation, LKD layer 164′ and NFD layer 162 are deposited in the same process chamber, such as in the same PECVD chamber. In other words, LKD layer 164′ and NFD layer 162 are formed “in-situ.”

Referring to FIG. 5, oxygen treatment 165 may drive oxygen into LKD layer 164′ and/or improve (e.g., strengthen) oxygen bonding of LKD layer 164′. Oxygen-treated LKD layer 164 thus has an oxygen content that is greater than an oxygen content of LKD layer 164′. In some embodiments, an oxygen content of LKD layer 164′ is less than about 50 at %, and oxygen treatment 165 increases the oxygen content, such that oxygen-treated LKD layer 164 has an oxygen content that is greater than or equal to about 50 at %. In some embodiments, oxygen treatment 165 increases a density of LKD layer 164′, such that a density of oxygen-treated LKD layer 164 is greater than a density of LKD layer 164. In some embodiments, oxygen treatment 165 increases Si—O bonding, C—O bonding, O—O bonding, O—N bonding, other types of oxygen bonding, or combinations thereof. For example, an amount of oxygen bonding and/or a strength of oxygen bonds in oxygen-treated LKD layer 164 may be greater than an amount of oxygen bonding and/or a strength of oxygen bonds in LKD layer 164′. Increasing density and enhancing oxygen bonding in LKD layer 164′ (and thus providing tri-layer ESL 160 with denser, oxygen-treated LKD layer 164 having stronger oxygen bonding) may reduce undesirable oxygen outgassing from tri-layer ESL 160 during subsequent thermal processes.

In some embodiments, oxygen treatment 165 is an oxygen plasma treatment, such as an O₂ plasma treatment. In some embodiments, the oxygen plasma treatment includes flowing an oxygen-containing precursor gas (e.g., O₂) and a carrier gas (e.g., He) into a process chamber, generating an oxygen-containing plasma therefrom, and bombarding LKD layer 164′ with plasma-excited oxygen-containing species (i.e., reactive species) of the oxygen-containing plasma. The reactive species may include radicals, ions, neutrals, electrons, photons, or combinations thereof. The reactive species may react with LKD layer 164′, for example, by adsorbing on the surfaces thereof and triggering chemical reactions that change a composition of LKD layer 164′ (e.g., increasing its oxygen content) and/or producing by-products that desorb from the surfaces thereof. In some embodiments, the oxygen-containing plasma includes excited neutral atoms and/or molecules (e.g., oxygen radicals, such as O*, O₂*, etc.), ionized atoms and/or molecules (e.g., oxygen ions, such as O₂⁺, O₂⁻, O⁺, O⁻, etc.), atoms and/or molecules (e.g., O₂, O, etc.), or combinations thereof. The oxygen-containing gas may include O₂ and/or other suitable oxygen-containing precursor (e.g., the plasma activation process is an O₂ plasma treatment). The carrier gas may be a noble gas and/or an inert gas, such as argon, helium, xenon, neon, krypton, other suitable gas, or combinations thereof. Parameters of oxygen treatment 165 are tuned to enhance oxygen bonding (e.g., with silicon, carbon, nitrogen, or combinations thereof) in LKD layer 164′, increase a density of LKD layer 164′, increase an oxygen content in LKD layer 164′, provide desired oxidation of LKD layer 164′, or combinations thereof, such as a flow rate and/or a concentration of an oxygen-containing precursor gas, a flow rate and/or a concentration of a carrier gas, a ratio of the oxygen-containing precursor gas to the carrier gas, temperature, pressure, time, power, a bias (voltage) for exciting the plasma and/or accelerating the plasma, a tilt angle, other suitable parameters, or combinations thereof.

The present disclosure further recognizes that undesirable oxidation occurs more readily between an ESL and a source/drain when an oxygen content at an ESL-source/drain interface is greater than 50 at %, yet further recognizes that an oxygen treatment, such as oxygen treatment 165, may improve ESL quality, for example, by increasing its density and/or improving its composition (e.g., by strengthening and/or increasing oxygen bonding therein). Tri-layer ESL 160 is thus provided with a bilayer low-k dielectric portion—NFD layer 162 interfacing with source/drain structure 150 and oxygen-treated LKD layer 164 interfacing with NFD layer 162—where no oxygen treatment is performed on NFD layer 162, thereby minimizing oxygen content at the ESL-source/drain interface, and oxygen treatment 165 is performed on oxygen-treated LKD layer 164′, thereby improving quality of the bilayer low-k dielectric portion without substantially increasing oxygen content at the ESL-source/drain interface. In some embodiments, oxygen treatment 165 may also increase a density of NFD layer 162, such that a density of NFD layer 162 after oxygen treatment 165 is greater than a density of NFD layer 162 before oxygen treatment 165. In some embodiments, oxygen treatment 165 may also enhance oxygen bonding in NFD layer 162, such that oxygen bonding in NFD layer 162 after oxygen treatment 165 is greater than oxygen bonding in NFD layer 162 before oxygen treatment 165. However, since LKD layer 164′ masks NFD layer 162 during oxygen treatment 165, any such increases in density and/or improvements in oxygen bonding are achieved without increasing oxygen content in NFD layer 162 too much. For example, oxygen content at an interface of NFD layer 162 and source/drain structure 150 (i.e., at the ESL-source/drain interface) remains less than 50 at % even after oxygen treatment 165.

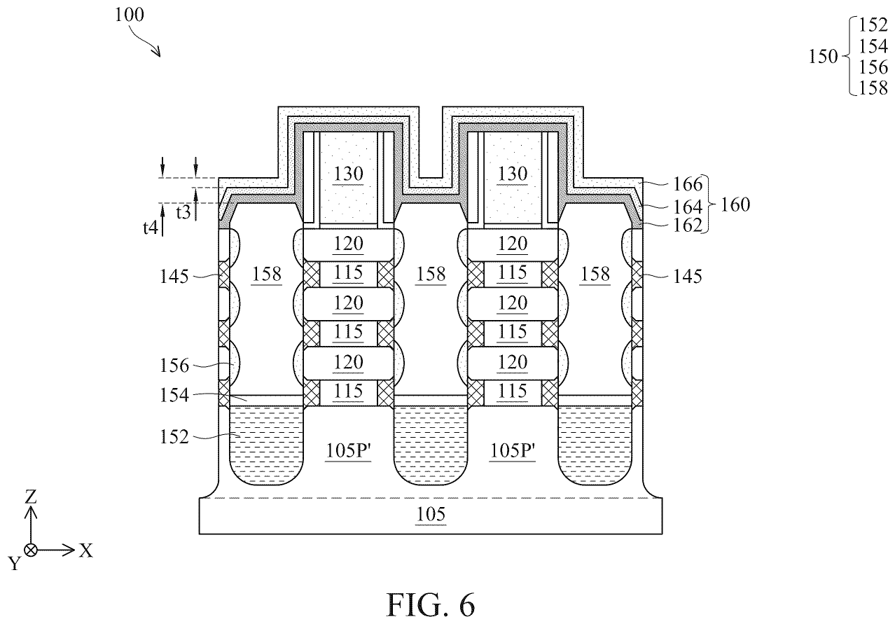

Referring to FIG. 6, dielectric layer 166 is formed over oxygen-treated LKD layer 164. In the depicted embodiment, dielectric layer 166 is formed directly on oxygen-treated LKD layer 164. Dielectric layer 166 has a thickness t3 that is less than the spacing between the adjacent gate structures 128, such that dielectric layer 166 also partially fills the spacing (and/or distance s) between the adjacent gate structures 128. Further, a thickness t4 of tri-layer ESL 160 (i.e., a sum of thickness t3, thickness t2, and thickness t1) is less than the spacing between the adjacent gate structures 128. Thickness t3 is greater than each of thickness t2 and thickness t1, and thickness t3 may be the same, greater than, or less than a sum of thickness t2 and thickness t1. In some embodiments, thickness t3 is about 2 nm to about 3 nm.

Dielectric layer 166 is formed of a dielectric material having a dielectric constant that is greater than about 3.9, and the dielectric constant of dielectric layer 166 is greater than the dielectric constant of oxygen-treated LKD layer 164. Dielectric layer 166 is also formed of a dielectric material that is different than a subsequently formed ILD layer (e.g., a silicon oxide layer) to provide adequate etch selectivity between tri-layer ESL 160 and a subsequently formed ILD layer. For example, when an etching process is performed on the subsequently formed ILD layer to form a source/drain contact opening therein, an etch rate of the dielectric material of dielectric layer 166 to a given etchant of the etching process is sufficiently less than an etch rate of the subsequently formed ILD layer to the given etchant so that dielectric layer 166 may function as an etch stop and protect underlying source/drain structures 150 from the etching process. Without dielectric layer 166, adequate etch selectivity may not be provided between an ESL overlying source/drain structures 150 and the subsequently formed ILD layer. For example, the given etchant may have low etch selectivity between a low-k dielectric ESL, such as the bilayer low-k dielectric portion of tri-layer ESL 160 (e.g., oxygen-treated LKD layer 164/or NFD layer 162), and the subsequently formed ILD layer, thereby negating the ESL's function as an etch stop. In some embodiments, dielectric layer 166 is formed of a dielectric material having a dielectric constant that is about 4 to about 10 (i.e., 4≤k≤10). For example, dielectric layer 166 includes silicon and nitrogen, and dielectric layer 166 is a silicon nitride layer. In such example, a dielectric constant of dielectric layer 166 may be about 6.5.

Dielectric layer 166 is deposited in a different process chamber than oxygen-treated LKD layer 164 and NFD layer 162, and dielectric layer 166 is formed by a different type of deposition process. For example, dielectric layer 166 is formed by atomic layer deposition (ALD), instead of CVD, and dielectric layer 166 is formed in an ALD chamber. In some embodiments, dielectric layer 166 is formed by CVD, instead of ALD, but in a different CVD chamber than that in which oxygen-treated LKD layer 164 and NFD layer 162 are formed. In some embodiments, dielectric layer 166 is formed by another suitable process.

A dielectric constant of tri-layer ESL 160 thus decreases from top (e.g., dielectric layer 166) to bottom (e.g., NFD layer 162). For example, the dielectric constant of tri-layer ESL 160 may decrease from about 6.5 to about 3.6 from top to bottom. In some embodiments, an upper portion of tri-layer ESL 160 (e.g., dielectric layer 166, which may interface with an overlying ILD layer) has a dielectric constant of about 5 to about 8, a middle portion of tri-layer ESL 160 (e.g., oxygen-treated LKD layer 164 interfacing with dielectric layer 166 and NFD layer 162) has a dielectric constant of about 3.7 to about 4.5, and a lower portion of tri-layer ESL 160 (e.g., NFD layer 162 interfacing with source/drain structure 150 and gate spacers 132) has a dielectric constant of about 3.6 to about 3.7. For example, dielectric layer 166 (e.g., SiN layer) has a dielectric constant of about 6.5, oxygen-treated LKD layer 164 (e.g., SiOC layer) has a dielectric constant of about 3.8, and NFD layer 162 (e.g., SiOC layer) has a dielectric constant of about 3.7. In another example, dielectric layer 166 (e.g., SiN layer) has a dielectric constant of about 6.5, oxygen-treated LKD layer 164 (e.g., SiOCN layer) has a dielectric constant of about 4.3, and NFD layer 162 (e.g., SiOC layer) has a dielectric constant of about 3.7. In yet another example, dielectric layer 166 (e.g., SiN layer) has a dielectric constant of about 6.5, oxygen-treated LKD layer 164 (e.g., SiOC layer) has a dielectric constant of about 3.7, and NFD layer 162 (e.g., SiOC layer) has a dielectric constant of about 3.6. Parameters of the deposition processes, such as the PECVD processes and the ALD process, may be tuned to provide NFD layer 162, oxygen-treated LKD layer 164, and dielectric layer 166 with desired dielectric constants, along with providing tri-layer ESL 160 with a dielectric constant that decreases from top to bottom, such that tri-layer ESL 160 may provide sufficient etch selectivity while also exhibiting a lower effective dielectric constant (and thereby lowering effective capacitance).

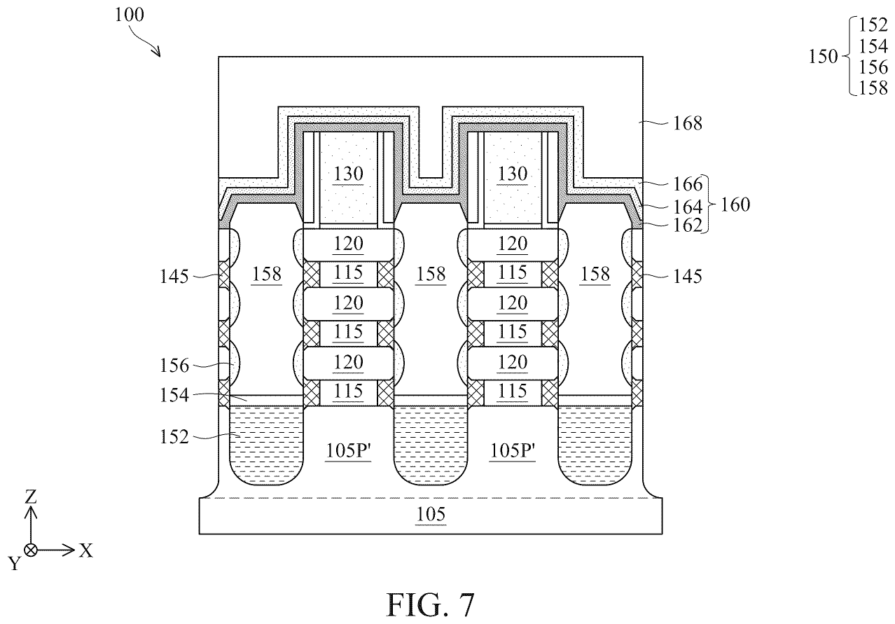

Referring to FIG. 7, an interlayer dielectric (ILD) layer 168 is formed over tri-layer ESL 160. In the depicted embodiment, ILD layer 168 is formed directly on dielectric layer 166 of tri-layer ESL 160, and ILD layer 168 fills a remainder of the spacing (and/or distance s) between the adjacent gate structures 128. ILD layer 168 may be formed by CVD, flowable CVD (FCVD), a high aspect ratio deposition (HARP) process, a high-density plasma CVD (HDPCVD), other suitable deposition process, or combinations thereof.

ILD layer 168 includes a dielectric material that is different than a dielectric material of dielectric layer 166 to enable selective etching therebetween. In the depicted embodiment, ILD layer 168 is a dielectric layer that includes silicon and oxygen. In some embodiments, a dielectric constant of ILD layer 168 is less than a dielectric constant of dielectric layer 166. For example, ILD layer 168 may be a silicon oxide layer (e.g., an SiO₂ layer), which may have a dielectric constant of about 3.9 (k≈3.9). In another example, ILD layer 168 may be a porous silicon oxide layer, which may be configured to have a dielectric constant less than about 2.5 (k≈2.5). In yet another example, ILD layer 168 may be a carbon-doped oxide layer (e.g., an SiOC layer), which may be configured to have a dielectric constant less than about 2.5 (k≈2.5). In some embodiments, ILD layer 168 includes silicon oxide, carbon-doped oxide, silicon oxynitride, tetraethylorthosilicate (TEOS)-formed oxide, PSG, BSG, boron-doped PSG (BPSG), fluorine-doped silicate glass (FSG), xerogel, aerogel, amorphous fluorinated carbon, parylene, benzocyclobutene (BCB)-based dielectric material, polyimide, other suitable dielectric material, or combinations thereof. In some embodiments, ILD layer 168 has a multilayer structure.

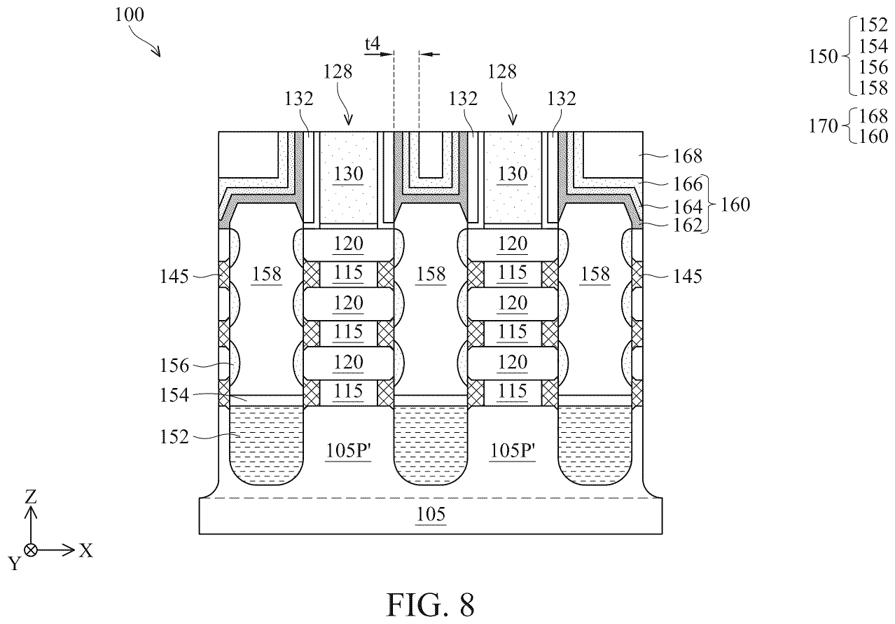

Referring to FIG. 8, a chemical mechanical polishing (CMP) process and/or other planarization process is performed on ILD layer 168 and tri-layer ESL 160. The CMP process is performed until reaching and exposing gate structures 128, such as dummy gate stacks 130 thereof. The CMP process may remove portions of ILD layer 168 and portions of tri-layer ESL 160 that extend above and/or are disposed over tops of gate structures 128. Remainders of ILD layer 168 and tri-layer ESL 160 form a device-level dielectric layer 170 over source/drain structures 150. Device-level dielectric layer 170 may fill spaces between adjacent gate structures 128 (e.g., between gate spacers 132 thereof) and/or spaces between adjacent source/drain structures 150 (e.g., along the y-direction and/or in the Y-Z plane). In some embodiments, dummy gate stacks 130 (e.g., hard masks thereof) and/or gate spacers 132 function as a CMP stop layer. In some embodiments, the CMP process is performed for a time sufficient to expose dummy gate stacks 130. The CMP process may planarize a top surface of device-level dielectric layer 170 (which may be formed by ILD layer 168 and each layer of tri-layer ESL 160), top surfaces of dummy gate stacks 130, and top surfaces of gate spacers 132. The planarized top surfaces may form a substantially planar surface of device 100 after the CMP process.

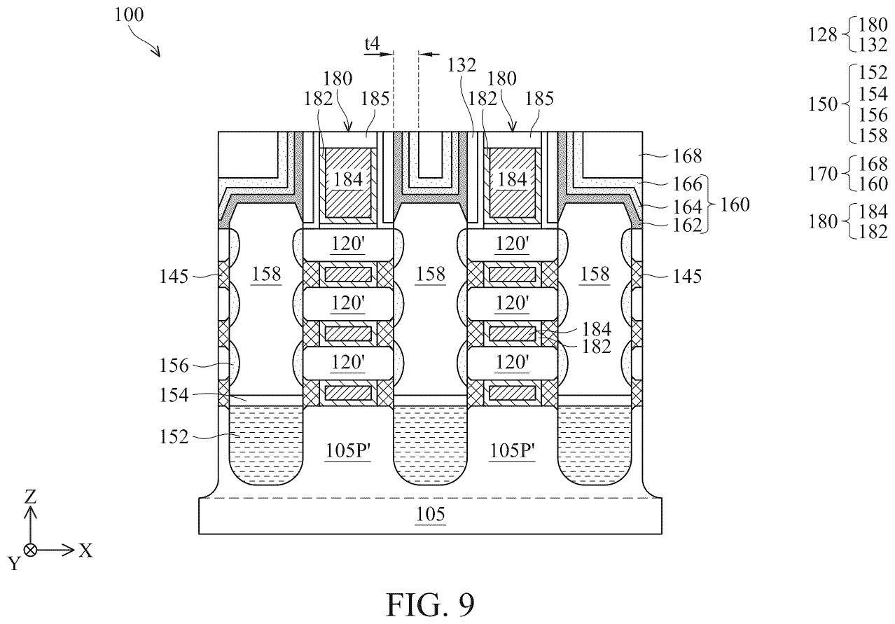

Referring to FIG. 9, in some embodiments, a gate replacement process may be performed to replace dummy gate stacks 130 with gate stacks 180. In some embodiments, dummy gate stacks 130 are removed to form gate openings (e.g., between gate spacers 132) that expose multilayer stack 110, such as semiconductor layers 120 and sacrificial layers 115 thereof, in the channel regions of device 100. For example, an etching process selectively removes dummy gate stacks 130 with negligible (to no) removal of device-level dielectric layer 170, gate spacers 132, inner spacers 145, sacrificial layers 115, semiconductor layers 120, or combinations thereof. The etching process is a dry etch, a wet etch, other suitable etch, or combinations thereof. In some embodiments, the etching process may use a patterned mask layer as an etch mask, and the patterned mask layer may cover device-level dielectric layer 170 and/or gate spacers 132 and have openings therein that expose dummy gate stacks 130.

During the gate replacement process, before forming gate stacks 180, a channel release process may be performed to form suspended channel layers. For example, sacrificial layers 115 exposed by the gate openings are selectively removed to form gaps between semiconductor layers 120 and gaps between semiconductor layers 120 and mesas 105P′, thereby suspending semiconductor layers 120 in the channel regions. In the depicted embodiment, each channel region has three suspended semiconductor layers 120, which are referred to hereafter as channel layers 120′, vertically stacked along the z-direction for providing three channels through which current can flow between respective source/drain structures 150 during operation of transistors of device 100. In some embodiments, an etching process selectively etches sacrificial layers 115 with minimal (to no) etching of semiconductor layers 120, mesas 105P′, gate spacers 132, inner spacers 145, device-level dielectric layer 170, or combinations thereof. In some embodiments, an etchant is selected for the etch process that etches silicon germanium (e.g., sacrificial layers 115) at a higher rate than silicon (e.g., semiconductor layers 120 and mesas 105P′) and dielectric materials (e.g., gate spacers 132, inner spacers 145, device-level dielectric layer 170, etc.) (i.e., the etchant has a high etch selectivity with respect to silicon germanium). In some embodiments, an etchant is selected for the etching process that etches a dielectric material having a first composition (e.g., sacrificial layers 115) at a higher rate than silicon (e.g., semiconductor layers 120 and mesas 105P′) and dielectric materials having compositions different than the first composition (e.g., gate spacers 132, inner spacers 145, device-level dielectric layer 170, etc.) (i.e., the etchant has a high etch selectivity with respect to the dielectric material having the first composition). The etching process is a dry etch, a wet etch, other suitable etch, or combinations thereof. In some embodiments, before performing the etching process, an oxidation process may convert sacrificial layers 115 into silicon germanium oxide layers, and the etching process may then remove the silicon germanium oxide layers. In some embodiments, an etching process is performed to modify a profile of semiconductor layers 120/channel layers 120′ to achieve target channel dimensions/shapes.

Gate stacks 180 (also referred to as high-k/metal gates) may then be formed in the gate openings and/or the gaps. Gate stacks 180 have portions disposed between respective gate spacers 132 and portions disposed between respective inner spacers 145. Gate stacks 180 are further disposed between channel layers 120′ and between channel layers 120′ and mesas 105P′. In the depicted embodiment, where device 100 includes GAA transistors, gate stacks 180 may surround and engage respective channel layers 120′, for example, in the Y-Z plane (see, e.g., FIG. 16A). In some embodiments, gate stacks 180 may wrap and/or partially surround respective channel layers 120′ (i.e., be disposed on at least two sides thereof).

Each gate stack 180 may include a gate dielectric 182. Gate dielectrics 182 are disposed on channel layers 120′, mesas 105P′, inner spacers 145, gate spacers 132, or combinations thereof. Gate dielectrics 182 may have the same or different compositions and/or configurations. Gate dielectrics 182 include at least one dielectric layer, such as an interfacial layer and/or a high-k dielectric layer. The interfacial layer includes a dielectric material, such as SiO₂, SiGeOₓ, HfSiO, SiON, other dielectric material, or combinations thereof. The high-k dielectric layer includes a high-k dielectric material, which generally refers to dielectric materials having a dielectric constant greater than a dielectric constant of silicon dioxide, such as HfO₂, HfSiO, HfSiO₄, HfSiON, HfLaO, HfTaO, HfIiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₃, Y₂O₃, SrTiO₃, BaZrO, BaTiO₃ (BTO), (Ba,Sr)TiO₃ (BST), HfO₂—Al₂O₃, other high-k dielectric material, or combinations thereof. In some embodiments, each gate dielectric 182 may include a hafnium-based oxide (e.g., HfO₂) layer and/or a zirconium-based oxide (e.g., ZrO₂) layer.

Each gate stack 180 may include a gate electrode 184. Gate electrodes 184 are disposed over gate dielectrics 182. Gate electrodes 184 may have the same or different compositions and/or configurations, and gate electrodes 184 include at least one electrically conductive layer formed of an electrically conductive material, which may include Al, Cu, Ti, Ta, W, Mo, Co, TaN, NiSi, CoSi, TiN, WN, TiAl, TiAlN, TaCN, TaC, TaSiN, other electrically conductive constituent, or combinations thereof. In some embodiments, gate electrodes 184 include a work function layer. The work function layer is a conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, gate electrodes 184 include a bulk layer over gate dielectric 182 and/or the work function layer. The bulk layer may include Al, W, Cu, Ti, Ta, TiN, TaN, polysilicon, other suitable metal(s) and/or alloys thereof, or combinations thereof. In some embodiments, gate electrodes 184 include a barrier layer over the work function layer and/or gate dielectric 182. The barrier layer includes a material that may prevent diffusion and/or reaction of constituents between adjacent layers and/or promotes adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

Forming gate stacks 180 may include depositing gate dielectric material (e.g., interfacial layers, high-k dielectric layers, etc.) that partially fill the gate openings, depositing gate electrode material (e.g., work function layers, barrier layers, bulk layers, etc.) that fill remainders of the gate openings, and performing a planarization process to remove portions of the gate dielectric material and/or portions of the gate electrode material over device-level dielectric layer 170. In some embodiments, such as depicted, fabrication of device 100 may further include etching back gate stacks 180 and forming hard masks (e.g., self-aligned cap (SAC) structures 185) over the etched-back gate stacks 180. SAC structures 185 include a material that is different than device-level dielectric layer 170 (e.g., ILD layer 168 thereof) and/or subsequently formed dielectric layers to achieve etch selectivity. In some embodiments, SAC structures 185 include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, SAC structures 185 include metal and oxygen and/or nitrogen, such as aluminum oxide, aluminum nitride, aluminum oxynitride, zirconium oxide, zirconium nitride, hafnium oxide, zirconium aluminum oxide, other metal oxide, other metal nitride, or combinations thereof. Though the depicted embodiment fabricates gate stacks 180 according to a gate last process, the present disclosure contemplates embodiments where the metal gate stacks of device 100 may be fabricated according to a gate first process or a hybrid gate last/gate first process.

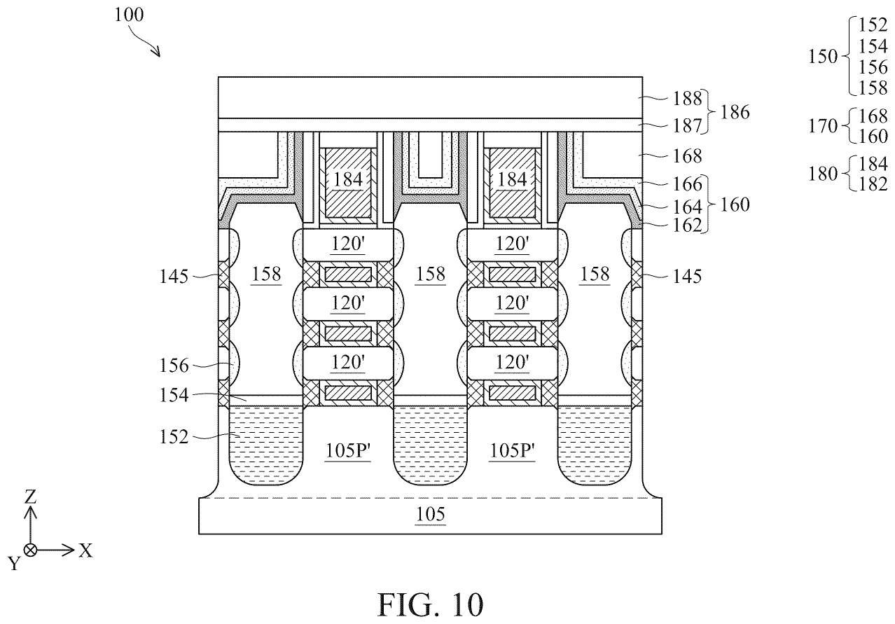

Referring to FIGS. 10-15, a source/drain contact is formed in device-level dielectric layer 170 to one of source/drain structures 150. Referring to FIG. 10, a dielectric layer 186 may be formed over device-level dielectric layer 170 and gate structures 128. In some embodiments, dielectric layer 186 includes a contact etch stop layer (CESL) 187 and an ILD layer 188. ILD layer 188 may be configured and/or formed similar to ILD layer 168. For example, ILD layer 188 includes a dielectric material, including, for example, silicon oxide, carbon doped silicon oxide, TEOS-formed oxide, PSG, BSG, BPSG, FSG, xerogel, aerogel, amorphous fluorinated carbon, parylene, BCB-based dielectric material, polyimide, other suitable dielectric material, or combinations thereof. The dielectric material may be a same dielectric material as or a different dielectric material than that of ILD layer 168. In some embodiments, ILD layer 188 is a low-k dielectric layer, such as a silicon-and-oxygen comprising dielectric layer having a dielectric constant less than about 3.9, and in some embodiments, less than about 2.5.

CESL 187 includes a material different than ILD layer 188 to enable etching selectivity therebetween, such as a dielectric material that is different than the dielectric material of ILD layer 188. In some embodiments, CESL 187 includes silicon and nitrogen. For example, CESL 187 is a silicon nitride layer and/or a silicon oxynitride layer. The present disclosure contemplates ILD layer 188 and/or CESL 187 having a multilayer structure and/or including multiple dielectric materials. In some embodiments, forming dielectric layer 186 includes depositing CESL 187 over device-level dielectric layer 170, depositing an ILD layer 188 over CESL 187, and performing a CMP and/or other planarization process on ILD layer 188.

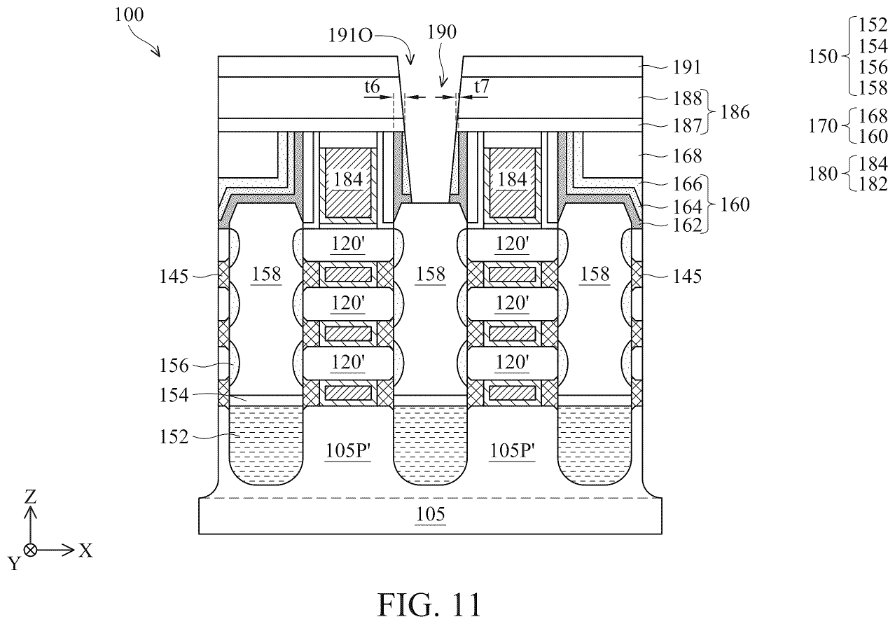

Referring to FIG. 11, a source/drain contact opening 190 is formed that exposes a respective one of source/drain structures 150. For example, source/drain contact opening 190 extends through ILD layer 188, CESL 187, ILD layer 168, and tri-layer ESL 160 to expose one of source/drain structures 150 disposed between gate structures 128. Portions of tri-layer ESL 160 along sidewalls of gate spacers 132 may be removed when forming source/drain contact opening 190. In the depicted embodiment, dielectric layer 166 is completely removed from along sidewalls of gate spacers 132, and oxygen-treated LKD layer 164 is partially removed from along sidewalls of gate spacers 132. In such embodiments, source/drain contact opening 190 has sidewalls formed by ILD layer 188, CESL 187, oxygen-treated LKD layer 164, and NFD layer 162. Further, in such embodiments, thickness t4 of portions of tri-layer ESL 160 along sidewalls of gate spacers 132 is reduced to a thickness t6. In some embodiments, thickness t6 is about 0.75 nm to about 2.75 nm. For example, thickness t6 may be about 1.5 nm to about 1.75 nm. Further, in such embodiments, thickness t2 of oxygen-treated LKD layer 164 may be reduced to a thickness t7. In some embodiments, thickness t7 is less than 1 nm.

In some embodiments, depending on a cross-sectional profile and/or shape of source/drain contact opening 190, a thickness of oxygen-treated LKD layer 164 along sidewalls of gate spacers 132 may be substantially uniform or vary along a gate height direction (e.g., along the z-direction). In the depicted embodiment, source/drain contact opening 190 has a width that decreases from top to bottom (i.e., source/drain contact opening 190 has a tapered width), and the thickness of oxygen-treated LKD layer 164 increases from top to bottom thereof (i.e., oxygen-treated LKD layer 164 has a tapered thickness along sidewalls of gate spacers 132). For example, the thickness of oxygen-treated LKD layer 164 increases from thickness t7 to thickness t2. In some embodiments, oxygen-treated LKD layer 164 is partially removed from top to bottom thereof along sidewalls of gate spacers 132, and the thickness of oxygen-treated LKD layer 164 increases from thickness t7 to a thickness that is greater than thickness t7, but less than thickness t2. The present disclosure contemplates various cross-sectional profiles and/or shapes for source/drain contact opening 190. For example, source/drain contact opening 190 may have a tapered width that increases from top to bottom, and in such embodiments, the thickness of oxygen-treated LKD layer 164 may decrease from top to bottom. In another example, source/drain contact opening 190 may have a substantially uniform width from top to bottom (i.e., source/drain contact opening 190 may have substantially vertical sidewalls), and in such embodiments, the thickness of oxygen-treated LKD layer 164 may be substantially uniform from top to bottom. In such embodiments, the substantially uniform thickness of oxygen-treated LKD layer 164 may be thickness t2 or less than thickness t2, such as where it is partially removed). The present disclosure also contemplates forming more than one source/drain contact opening 190, such as source/drain contact openings to each of source/drain structures 150.

Device-level dielectric layer 170 and dielectric layer 186 may be patterned by a lithography and etching process. For example, forming source/drain contact opening 190 may include performing a lithography process to form a patterned mask layer 191 over ILD layer 188 and performing an etching process to transfer a pattern defined by one or more openings 1910 in patterned mask layer 191 (which overlap respective source/drain structures 150) to ILD layer 188, CESL 187, ILD layer 168, and tri-layer ESL 160. The lithography process may include forming a resist layer over ILD layer 188 (for example, by spin coating), performing a pre-exposure baking process, performing an exposure process using a mask, performing a post-exposure baking process, and performing a developing process. During the exposure process, the resist layer may be exposed to radiation energy (such as ultraviolet (UV) light, deep UV (DUV) light, or extreme UV (EUV) light), where the mask blocks, transmits, and/or reflects radiation to the resist layer depending on a mask pattern of the mask and/or mask type (for example, binary mask, phase shift mask, or EUV mask), such that an image is projected onto the resist layer that corresponds with the mask pattern. Alternatively, the exposure process may be implemented or replaced by other methods, such as maskless lithography, electron-beam writing, ion-beam writing, and/or nanoimprint technology. Since the resist layer is sensitive to radiation energy, exposed (or non-exposed) portions of the resist layer chemically change, and exposed (or non-exposed) portions of the resist layer are dissolved during the developing process depending on characteristics of the resist layer and characteristics of a developing solution used in the developing process. After development, the patterned resist layer includes a resist pattern that corresponds with the mask. In some embodiments, patterned mask layer 191 is the patterned resist layer. In some embodiments, the patterned resist layer is used as an etch mask to remove portions of a hard mask layer, thereby forming patterned mask layer 191. In some embodiments, patterned mask layer 191 includes a patterned resist layer and a patterned hard mask layer, and the pattered resist layer is disposed over the patterned hard mask layer. In the depicted embodiment, patterned mask layer 191 is formed directly on dielectric layer 186 (e.g., ILD layer 188 thereof). In some embodiments, dielectric layer 186 is omitted, and patterned mask layer 191 is formed directly on device-level dielectric layer 170 and gate structures 128.

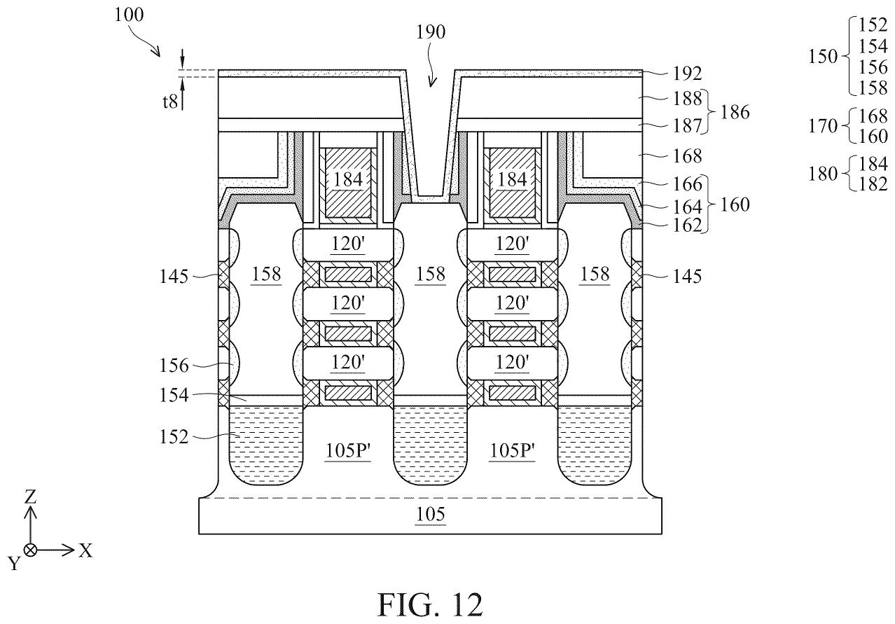

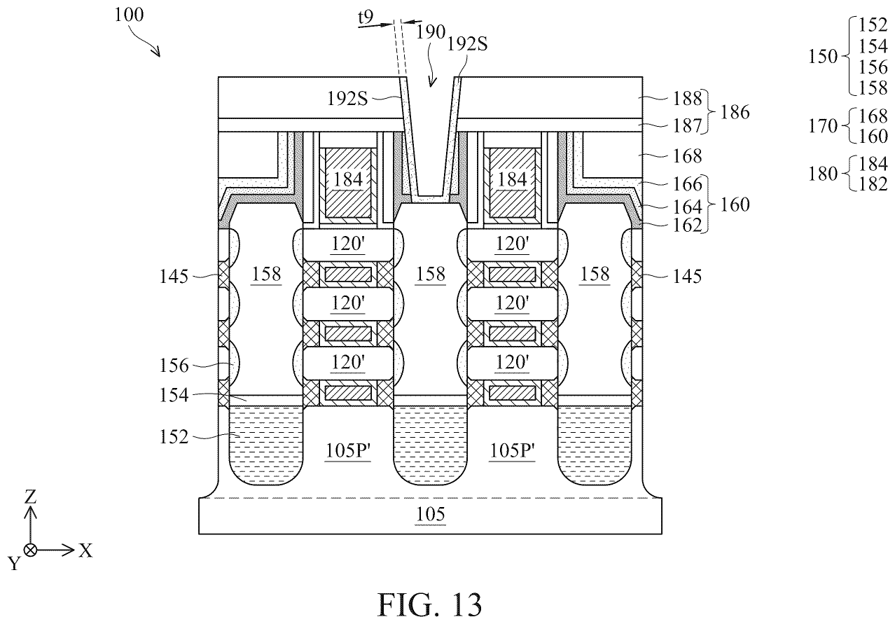

Referring to FIG. 12 and FIG. 13, contact spacers 192S are formed in and partially fill source/drain contact opening 190. Contact spacers 192S are formed along and cover sidewalls of source/drain contact opening 190. Referring to FIG. 12, after removing patterned mask layer 191 by any suitable process, a dielectric contact liner 192 may be deposited over dielectric layer 186 and partially fill source/drain contact opening 190. Dielectric contact liner 192 is disposed on a top surface of ILD layer 188, sidewalls of source/drain contact opening 190, and a bottom of source/drain contact opening 190. For example, dielectric contact liner 192 covers sidewalls of source/drain contact opening 190 formed by ILD layer 188, CESL 187, oxygen-treated LKD layer 164, and NFD layer 162. Dielectric contact liner 192 further covers a bottom of source/drain contact opening 190 formed by the exposed source/drain structure 150 (e.g., semiconductor layer 158 thereof). Dielectric contact liner 192 is deposited by any suitable process. For example, dielectric contact liner 192 is conformally deposited by ALD, such that dielectric contact liner 192 has a thickness t8 that is substantially uniform.

Dielectric contact liner 192 includes a dielectric material that is different than a dielectric material of ILD layer 188, oxygen-treated LKD layer 164, and NFD layer 162 to enable selective etching therebetween. The dielectric material may be configured to hinder and/or prevent diffusion of metal constituents from an electrically conductive portion of a source/drain contact into dielectric layer 186, ILD layer 168, tri-layer ESL 160, or combinations thereof. In the depicted embodiment, dielectric contact liner 192 includes silicon and nitrogen. For example, dielectric contact liner is a silicon nitride layer. In some embodiments, dielectric contact liner 192 is a metal oxide layer and/or a metal nitride layer.

Referring to FIG. 13, portions of dielectric contact liner 192 are removed by an etching process, such as a dry etch, a wet etch, other suitable etch, or combinations thereof. Remaining portions of dielectric contact liner 192 form contact spacers 192S, which cover sidewalls of source/drain contact opening 190. Accordingly, after the etching process, source/drain contact opening 190 has sidewalls formed by contact spacers 192S and bottoms formed by the exposed source/drain structure 150 (e.g., semiconductor layer 158 thereof). Contact spacers 192S extend lengthwise along the z-direction and have a thickness t9 (e.g., along the x-direction). In the depicted embodiment, thickness t9 is about equal to thickness t8. In some embodiments, the etching process may thin dielectric contact liner 192 along the x-direction and/or the y-direction, such that thickness t9 is less than thickness t8. In some embodiments, contact spacers 192S have substantially uniform thicknesses along their lengths. For example, thickness t9 is substantially the same from top to bottom of source/drain contact opening 190 (i.e., along the lengths of contact spacers 192S). In some embodiments, contact spacers 192S have tapered thicknesses along their lengths. For example, thickness t9 may increase from top to bottom of source/drain contact opening 190 (i.e., along the lengths of contact spacers 192S). In another example, thickness t9 may decrease from top to bottom of source/drain contact opening 190 (i.e., along the lengths of contact spacers 192S).

The etching process may selectively etch dielectric contact liner with minimal (to no) etching of ILD layer 188, CESL 187, oxygen-treated LKD layer 164, NFD layer 162, semiconductor layers 158, or combinations thereof. In some embodiments, an etchant is selected for the etching process that etches a dielectric material having a first composition (e.g., silicon nitride) at a higher rate than semiconductor materials (e.g., silicon and/or germanium) and dielectric materials having compositions different than the first composition (e.g., silicon oxycarbide, silicon oxide, silicon oxycarbonitride, etc.) (i.e., the etchant has a high etch selectivity with respect to the dielectric material having the first composition). In some embodiments, the etching process is an anisotropic etch, which generally refers to an etch process having different etch rates in different directions, such that the etch process removes material in specific directions. For example, the etching may have a vertical etch rate that is greater than a horizontal etch rate (in some embodiments, the horizontal etch rate equals zero). The anisotropic etch process thus removes material in substantially the vertical direction (here, z-direction) with minimal (to no) material removal in the horizonal direction (here, x-direction and/or y-direction). In such embodiments, the anisotropic etch removes portions of dielectric contact liner 192 on horizontally-oriented surfaces of device 100 (i.e., from top surface of ILD layer 188 and top surface of source/drain structure 150) but does not remove, or minimally removes, portions of dielectric contact liner 192 on vertically-oriented surfaces (i.e., portions of ILD layer 188, CESL 187, oxygen-treated LKD layer 164, and NFD layer 162 forming the sidewalls of source/drain contact opening, in the depicted embodiment).

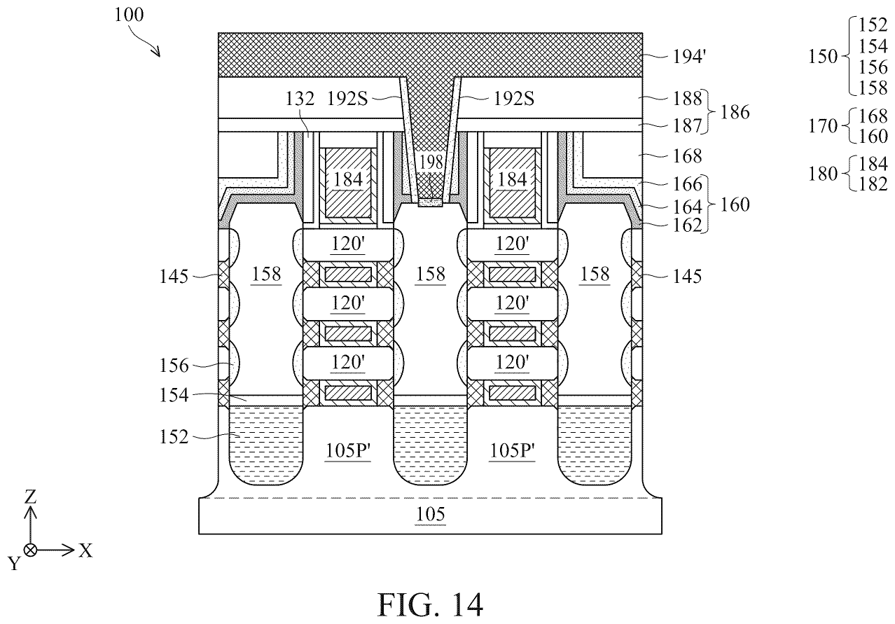

Referring to FIG. 14 and FIG. 15, a source/drain contact 194 may be formed by depositing an electrically conductive contact material 194′ over dielectric layer 186 and contact spacers 192S (FIG. 14) and performing a planarization process (e.g., a CMP process) to remove excess electrically conductive contact material 194′, such as that disposed over top surface of dielectric layer 186 (FIG. 15). A remainder of electrically conductive contact material 194′ forms source/drain contact 194. The planarization process may be performed until reaching and exposing dielectric layer 186. In some embodiments, ILD layer 188 may be a CMP stop layer, and the CMP process may planarize a top surface of device 100 (e.g., top surface of source/drain contact 194, a top surface of ILD layer 188, and top surfaces of contact spacers 192S).

Electrically conductive contact material 194′ includes tungsten, ruthenium, cobalt, molybdenum, copper, aluminum, titanium, tantalum, iridium, palladium, platinum, nickel, tin, gold, silver, other suitable metal, alloys thereof, or combinations thereof. In some embodiments, forming electrically conductive contact material 194′ includes depositing a metal bulk material, such as tungsten, cobalt, or ruthenium, over device 100. In such embodiments, source/drain contact 194 may include a tungsten plug, a cobalt plug, or a ruthenium plug. The metal bulk material may have a multilayer structure, such as a bulk layer disposed over a seed layer. The metal bulk material may be formed by a blanket deposition process, such as blanket CVD. In some embodiments, the blanket deposition process is physical vapor deposition (PVD), ALD, electroplating, electroless plating, other suitable process, or combinations thereof. In some embodiments, the metal bulk material is formed by a bottom-up deposition process, which generally refers to a deposition process that fills source/drain contact opening 190 from bottom to top. In some embodiments, the bottom-up deposition process includes multiple deposition/etch cycles, each of which may include depositing an electrically conductive material and etching back the electrically conductive material successively.

In some embodiments, source/drain contact 194 is barrier-free. For example, electrically conductive material 194′ includes a metal bulk material/layer, but not a barrier/liner material/layer. In such embodiments, a metal plug of source/drain contact 194 (e.g., formed by the metal bulk material/layer) may directly contact its surrounding dielectric material, such as contact spacers 192S (or ILD layer 188, CESL 187, and tri-layer ESL 160, such as in embodiments where contact spacers 192S are omitted). In some embodiments, source/drain contact 194 includes at least one liner/barrier layer between its metal plug and surrounding dielectric material. In such embodiments, forming electrically conductive contact material 194′ further includes depositing a barrier/liner material over dielectric layer 186 before depositing the metal bulk material. The barrier/liner material partially fills and lines source/drain contact opening 190, and the metal bulk material is formed over the barrier/liner material and fills a remainder of source/drain contact opening 190. In such embodiments, a barrier/liner is disposed between and separates a metal plug of source/drain contact 194 (e.g., formed by the metal bulk material/layer) from its surrounding dielectric material, such as contact spacers 192S (or ILD layer 188, CESL 187, and tri-layer ESL 160, such as in embodiments where contact spacers 192S are omitted). The barrier/liner material may promote adhesion between contact spacers 192S and the metal bulk material and/or prevent diffusion of metal constituents from the metal bulk material into adjacent dielectric material, such as contact spacers 192S, ILD layer 188, CESL 187, and tri-layer ESL 160, or combinations thereof. In some embodiments, the barrier/liner material includes tantalum, tantalum nitride, tantalum aluminum nitride, tantalum silicon nitride, tantalum carbide, titanium, titanium nitride, titanium silicon nitride, titanium aluminum nitride, titanium carbide, tungsten, tungsten nitride, tungsten carbide, molybdenum nitride, cobalt, cobalt nitride, ruthenium, palladium, or combinations thereof.

In some embodiments, a silicide structure 198 is formed over exposed source/drain structure 150 before or after forming electrically conductive material 194′. For example, silicide structure 198 may be formed by depositing a metal layer over semiconductor layer 158 and heating device 100, such as by an annealing process, to cause constituents of semiconductor layer 158 (e.g., silicon and/or germanium) to react with metal constituents in the metal layer. The metal layer includes any metal constituent suitable for promoting silicide formation, such as nickel, platinum, palladium, vanadium, titanium, cobalt, tantalum, ytterbium, zirconium, other suitable metal, or combinations thereof. Silicide structure 198 thus includes a metal constituent and a constituent of semiconductor layer 158 (e.g., silicon and/or germanium). In some embodiments, the metal layer is a titanium-containing layer, a cobalt-containing layer, or a nickel-containing layer, and silicide structure 198 includes titanium, cobalt, or nickel, and silicon and/or germanium. In such embodiments, silicide structure 198 may be a titanium silicide layer, a nickel silicide layer, or a cobalt silicide layer. In some embodiments, portions of semiconductor layer 158 are converted into silicide structure 198 during the silicidation process. Any un-reacted metal, such as remaining portions of the metal layer, is selectively removed by a suitable process, such as an etching process. Silicide structure 198 may be considered a portion of respective source/drain structure 150 or respective source/drain contact 194.

Source/drain contact 194 is coupled to source/drain structure 150 and/or silicide structure 198. Source/drain contact 194 is separated and electrically isolated from gate stacks 180 by contact spacers 192S, tri-layer ESL 160, and gate spacers 132. Since source/drain contact 194 and gate electrodes 184 of gate structures 128 are electrically conductive materials separated by dielectric material (e.g., gate spacers 132 and tri-layer ESL 160 (and, in some embodiments, contact spacers 192S)), a parasitic capacitor may form therebetween. Parasitic capacitance and/or capacitive coupling between source/drain contact 194 and gate electrodes 184 may degrade device performance, for example, by slowing down and/or delaying electrical signals. The disclosed tri-layer ESL 160 reduces the parasitic capacitance by reducing a dielectric constant of the dielectric material between source/drain contact 194 and gate electrodes 184. For example, since capacitance is directly proportional to a dielectric constant of a dielectric material between two electrically conductive plates (e.g., source/drain contact 194 and gate electrodes 184), capacitance decreases as a dielectric constant of the dielectric material decreases. In the depicted embodiment, because tri-layer ESL 160 is configured with a bilayer low-k dielectric layer (e.g., NFD layer 162 and oxygen-treated LKD layer 164) and dielectric layer 166, tri-layer ESL 160 provides desired etch selectivity between tri-layer ESL 160 (e.g., upper dielectric layer 166 (e.g., SiN layer)) and ILD layer 168 while exhibiting a lower effective capacitance than a nitride-only ESL, thereby providing the dielectric material between source/drain contact 194 and gate electrodes 184 with a lower effective capacitance. In particular, reducing a nitrogen content of an ESL formed over gate structures 128 and source/drain structures 150 (e.g., by configuring tri-layer ESL 160 with NFD layer 162 (e.g., SiOC layer), and in some embodiments, with a nitrogen-free oxygen-treated LKD layer 164 (e.g., SiOC layer with a higher oxygen content)) may provide the ESL with a dielectric constant that is less than 3.9. Lowering the effective capacitance may improve electrical signal transmission, thereby increasing device speed and/or improving overall device performance. Further, because tri-layer ESL 160 is configured with a dielectric constant that decreases from top to bottom, even if a portion of tri-layer ESL 160 is removed during source/drain contact formation and/or during additional fabrication of device 100, a dielectric constant of a remainder of tri-layer ESL 160 between source/drain contact 194 and gate electrodes 184 is lower than a dielectric constant of silicon oxide.

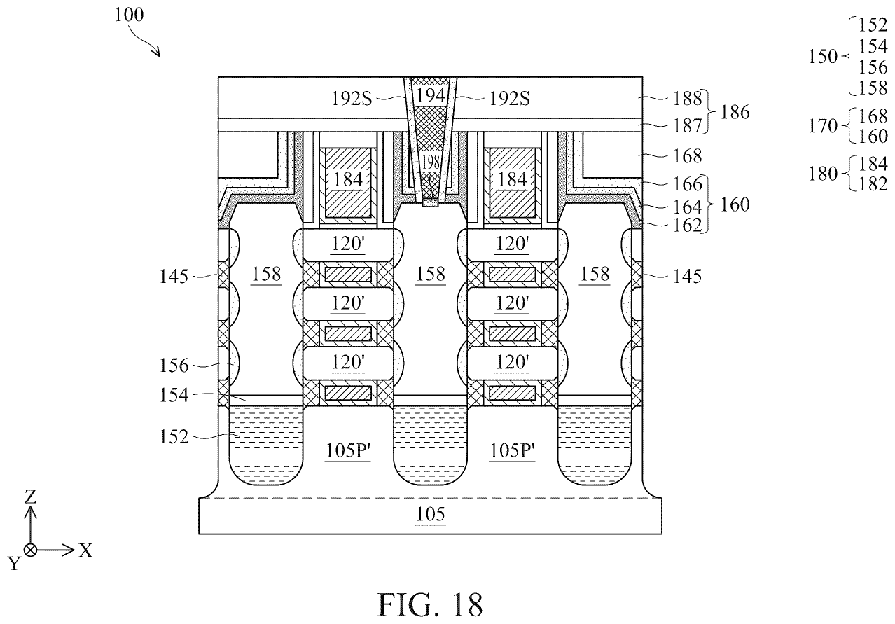

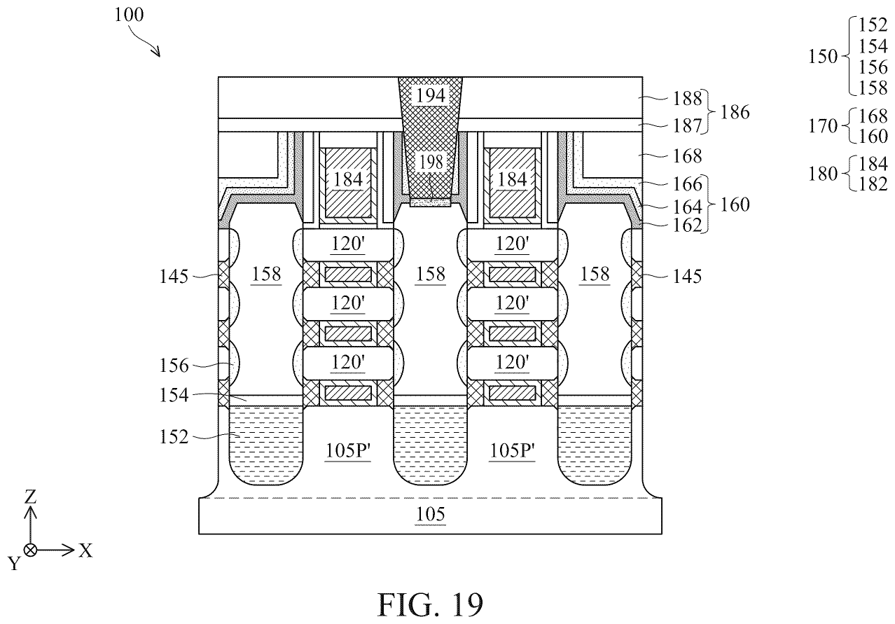

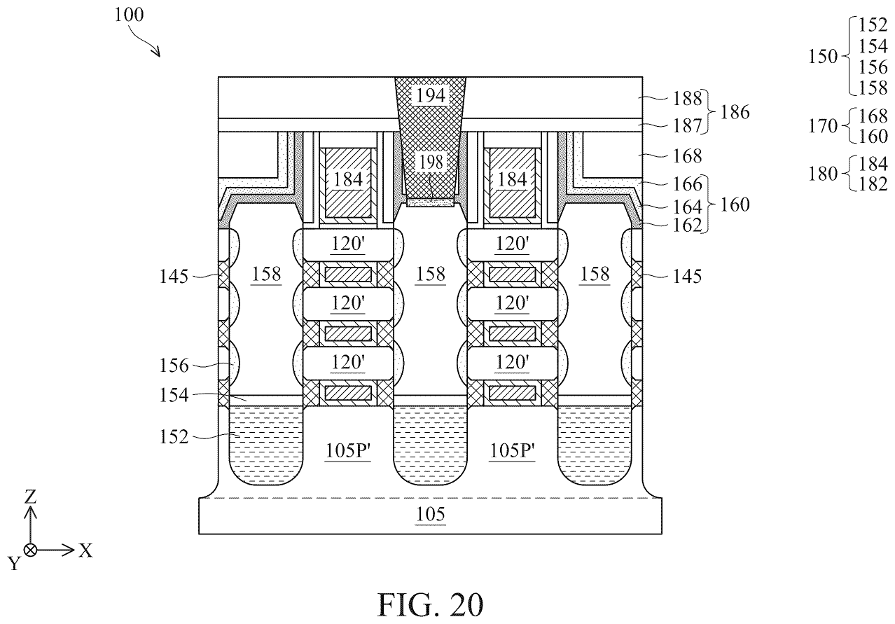

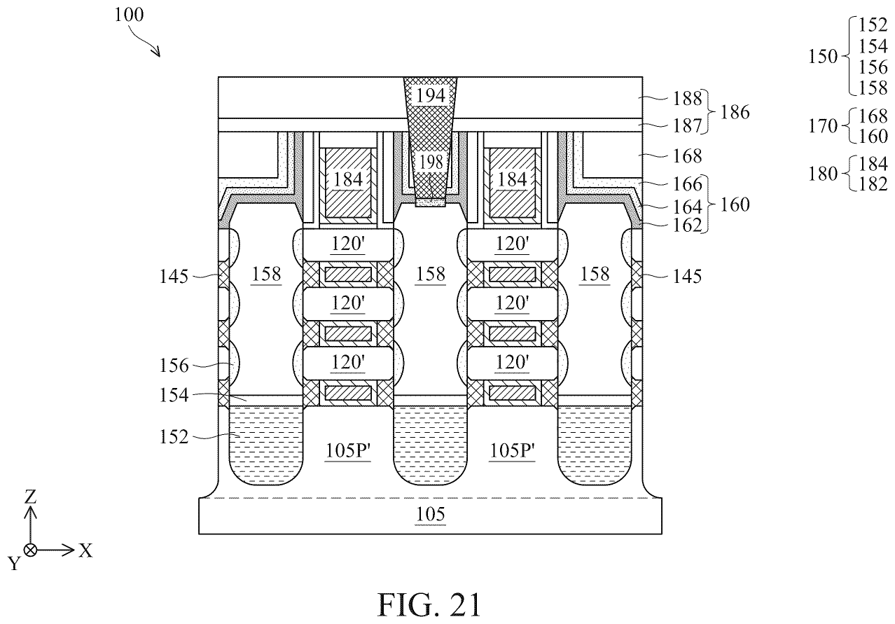

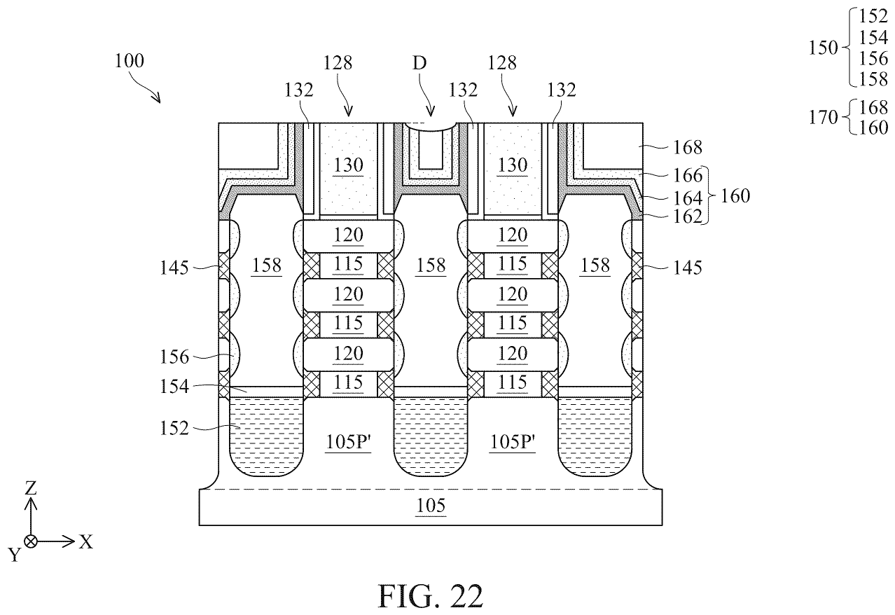

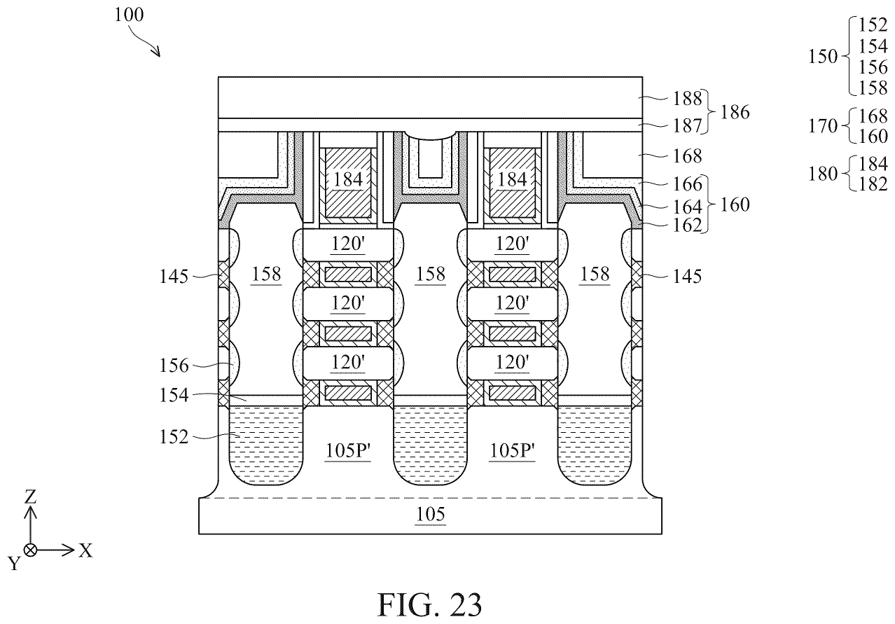

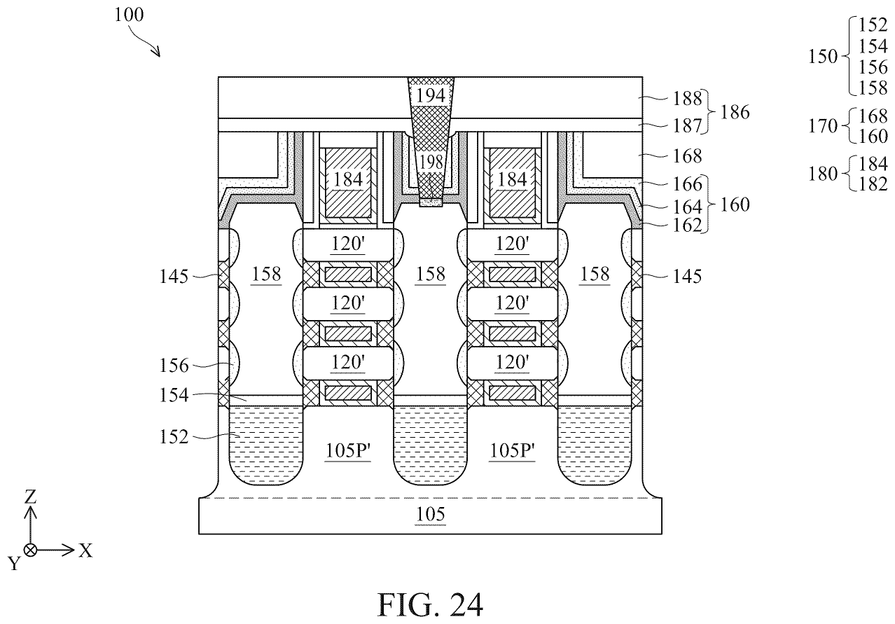

The present disclosure contemplates various configurations of tri-layer ESL 160 and source/drain contact 194 that may result from processing variations, such as those depicted in FIGS. 17-23. In some embodiments, at least a portion of oxygen-treated LKD layer 164 is completely removed from along sidewalls of gate spacers 132, such as depicted in FIG. 17. In such embodiments, NFD layer 162 of tri-layer ESL 160 is between a first portion of source/drain contact 190 and first portions of gate stacks 180 (e.g., upper portions thereof), while both NFD layer 162 and oxygen-treated LKD layer 164 of tri-layer ESL 160 are between a second portion of source/drain contact 190 and second portions of gate stacks 180 (e.g., lower portions thereof). In some embodiments, dielectric layer 166 is partially removed from along sidewalls of gate spacers 132, such as depicted in FIG. 18. In such embodiments, NFD layer 162 and oxygen-treated LKD layer 164 of tri-layer ESL 160 are between a first portion of source/drain contact 190 and first portions of gate stacks 180 (e.g., upper portions thereof), while NFD layer 162, oxygen-treated LKD layer 164, and dielectric layer 166 of tri-layer ESL 160 are between a second portion of source/drain contact 190 and second portions of gate stacks 180 (e.g., lower portions thereof). In some embodiments, contact spacers 192S are omitted from the source/drain contact structure of device 100, such that source/drain contact 194 directly contacts tri-layer ESL 160, such as depicted in FIGS. 19-21. In such embodiments, source/drain contact 194 may directly contact oxygen-treated LKD layer 164 (FIG. 19), NFD layer 162 and oxygen-treated LKD layer 164 (FIG. 20), or oxygen-treated LKD layer 164 and dielectric layer 166 (FIG. 21). In some embodiments, source/drain contact 194 or contact spacers 192S directly contact NFD layer 162, but not LKD layer 164 and dielectric layer 166, such as where these layers are completely removed when forming source/drain contact opening 190. In some embodiments, referring to FIG. 22, dishing D may result when ILD layer 168 and/or tri-layer ESL 160 are planarized, such as that described with respect to FIG. 8. In FIG. 22, the planarization process may completely remove an upper portion of dielectric layer 166 and partially remove an upper portion of oxygen-treated LKD layer 164. In such embodiments, CESL 187 (e.g., a silicon nitride layer) may fill dishing D, such as depicted in FIG. 23, and CESL 187 may also be disposed between gate stacks 180 (e.g., upper portions thereof) and source/drain contact 194 (and contact spacers 192S, in some embodiments), such as depicted in FIG. 24. In such embodiments, CESL 187 may be disposed between an upper portion of tri-layer ESL 160 and source/drain contact 194 (and contact spacers 192S, in some embodiments), such as depicted in FIG. 24.

The present disclosure provides for many different embodiments. An exemplary method includes forming a tri-layer etch stop layer over a source/drain by forming a nitrogen-free low-k dielectric layer on the source/drain, forming an oxygen-treated low-k dielectric layer on the nitrogen-free low-k dielectric layer, and forming a dielectric layer on the oxygen-treated low-k dielectric layer. The nitrogen-free dielectric layer has a first dielectric constant, the oxygen-treated low-k dielectric layer has a second dielectric constant that is greater than the first dielectric constant, and the dielectric layer has a third dielectric constant that is greater than the second dielectric constant and the first dielectric constant. In some embodiments, the nitrogen-free dielectric layer is formed to have a first thickness, the oxygen-treated low-k dielectric layer is formed to have a second thickness, and the dielectric layer is formed to have a third thickness. The third thickness is greater than each of the first thickness and the second thickness.

In some embodiments, the method further includes forming an interlayer dielectric layer over the tri-layer etch stop layer. In some embodiments, the method further includes removing a portion of the tri-layer etch stop layer and a portion of the ILD layer to form a source/drain contact opening that exposes the source/drain and forming a source/drain contact structure in the source/drain contact opening. In some embodiments, forming the dielectric layer includes performing an atomic layer deposition process.

In some embodiments, the nitrogen-free low-k dielectric layer and the oxygen-treated low-k dielectric layer are each formed of an oxygen-comprising dielectric material, wherein a first oxygen content of the oxygen-comprising dielectric material of the nitrogen-free low-k dielectric layer is less than a second oxygen content of the oxygen-comprising dielectric material of the oxygen-treated low-k dielectric layer. In some embodiments, the first oxygen content is less than about 50 atomic percent (at %) and the second oxygen content is greater than 50 at %.

In some embodiments, forming the nitrogen-free low-k dielectric layer includes depositing a first SiOC layer and forming the oxygen-treated low-k dielectric layer includes depositing a second SiOC layer and performing an oxygen treatment on the second SiOC layer. In some embodiments, the dielectric layer includes forming a SiN layer.

In some embodiments, forming the nitrogen-free low-k dielectric layer includes performing a first plasma enhanced chemical vapor deposition process and forming the oxygen-treated low-k dielectric layer includes performing a second plasma enhanced chemical vapor deposition process and performing an oxygen treatment after performing the second plasma enhanced chemical vapor deposition process. In some embodiments, no oxygen treatment is performed between performing the first plasma enhanced chemical vapor deposition process and the second plasma enhanced chemical vapor deposition process. In some embodiments, the first plasma enhanced chemical vapor deposition process implements a deposition temperature that is about 200° C. to about 600° C. and a deposition time that is about six minutes to about one hour. In some embodiments, the second plasma enhanced chemical vapor deposition process implements a deposition temperature that is about 200° C. to about 600° C. and a deposition time that is about six minutes to about one hour. In some embodiments, the second plasma enhanced chemical vapor deposition process deposits a low-k dielectric layer over the nitrogen-free low-k dielectric layer and the oxygen treatment exposes the low-k dielectric layer to an O₂ plasma.

Another exemplary method includes forming a contact etch stop layer over a source/drain by depositing a first SiOC layer on the source/drain, depositing a second SiOC layer on the first SiOC layer, performing an oxygen treatment on the second SiOC layer, and depositing a SiN layer on the oxygen-treated, second SiOC layer. The method further includes forming an interlayer dielectric layer on the contact etch stop layer and forming a source/drain contact to the source/drain. The source/drain contact is formed in the contact etch stop layer and the ILD layer. In some embodiments, no oxygen treatment is performed between depositing the first SiOC layer and depositing the second SiOC layer. In some embodiments, the first SiOC layer and the second SiOC layer are deposited in a same deposition process chamber. In some embodiments, the first SiOC layer is deposited by a first plasma-enhanced chemical vapor deposition (PECVD), and the second SiOC layer is deposited by a second PECVD. In some embodiments, the SiN layer is deposited by atomic layer deposition. In some embodiments, a deposition temperature of the depositing the first SiOC layer is less than about 600° C. In some embodiments, a deposition temperature of the depositing the second SiOC layer is less than about 600° C. In some embodiments, a deposition time of the depositing the first SiOC layer is less than about one hour. In some embodiments, a deposition time of the depositing the second SiOC layer is less than about one hour. In some embodiments, forming the source/drain contact to the source/drain includes completely removing a portion of the SiN layer and partially removing a portion of the second SiOC layer along a sidewall of a gate spacer.

An exemplary device structure includes a gate stack, a gate spacer disposed along a sidewall of the gate stack, a source/drain disposed adjacent to the gate spacer, a source/drain contact structure disposed on the source/drain, and a contact etch stop layer disposed between the gate spacer and the source/drain contact structure. The contact etch stop layer has a nitrogen-free portion interfacing with the source/drain and the gate spacer. In some embodiments, a dielectric constant of the nitrogen-free portion interfacing with the source/drain and the gate spacer is about 3.6 to about 3.7. In some embodiments, the nitrogen-free portion is a first silicon oxycarbide portion having a first oxygen content, and the contact etch stop layer further has a second silicon oxycarbide portion disposed over the first silicon oxycarbide portion. The second silicon oxycarbide portion has a second oxygen content that is greater than the first oxygen content. In some embodiments, the first silicon oxycarbide portion has a first carbon content, and the second silicon oxycarbide portion has a second carbon content. The second carbon content is different than (e.g., less than, in some embodiments) the first carbon content.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a tri-layer etch stop layer over a source/drain by:
forming a nitrogen-free low-k dielectric layer on the source/drain, wherein the nitrogen-free dielectric layer has a first dielectric constant,
forming an oxygen-treated low-k dielectric layer on the nitrogen-free low-k dielectric layer, wherein the oxygen-treated low-k dielectric layer has a second dielectric constant that is greater than the first dielectric constant, and
forming a dielectric layer on the oxygen-treated low-k dielectric layer, wherein the dielectric layer has a third dielectric constant that is greater than the second dielectric constant and the first dielectric constant;
forming an interlayer dielectric layer over the tri-layer etch stop layer;
removing a portion of the tri-layer etch stop layer and a portion of the ILD layer to form a source/drain contact opening that exposes the source/drain; and
forming a source/drain contact structure in the source/drain contact opening.

2. The method of claim 1, wherein:
the forming the nitrogen-free low-k dielectric layer includes depositing a first SiOC layer;
the forming the oxygen-treated low-k dielectric layer includes depositing a second SiOC layer and performing an oxygen treatment on the second SiOC layer; and
the forming the dielectric layer includes forming a SiN layer.

3. The method of claim 1, wherein:
the forming the nitrogen-free low-k dielectric layer includes performing a first plasma enhanced chemical vapor deposition process;
the forming the oxygen-treated low-k dielectric layer includes performing a second plasma enhanced chemical vapor deposition process and performing an oxygen treatment after performing the second plasma enhanced chemical vapor deposition process; and
the forming the dielectric layer includes performing an atomic layer deposition process.

4. The method of claim 3, wherein no oxygen treatment is performed between performing the first plasma enhanced chemical vapor deposition process and the second plasma enhanced chemical vapor deposition process.

5. The method of claim 3, wherein each of the first plasma enhanced chemical vapor deposition process and the second plasma enhanced chemical vapor deposition process implement a deposition temperature that is about 200° C. to about 600° C. and a deposition time that is about six minutes to about one hour.

6. The method of claim 3, wherein the second plasma enhanced chemical vapor deposition process deposits a low-k dielectric layer over the nitrogen-free low-k dielectric layer and the oxygen treatment exposes the low-k dielectric layer to an O₂ plasma.

7. The method of claim 1, wherein the nitrogen-free low-k dielectric layer and the oxygen-treated low-k dielectric layer are each formed of an oxygen-comprising dielectric material, wherein a first oxygen content of the oxygen-comprising dielectric material of the nitrogen-free low-k dielectric layer is less than a second oxygen content of the oxygen-comprising dielectric material of the oxygen-treated low-k dielectric layer.

8. The method of claim 7, wherein the first oxygen content is less than about 50 atomic percent (at %) and the second oxygen content is greater than 50 at %.

9. The method of claim 1, wherein:
the nitrogen-free dielectric layer is formed to have a first thickness,
the oxygen-treated low-k dielectric layer is formed to have a second thickness, and
the dielectric layer is formed to have a third thickness that is greater than each of the first thickness and the second thickness.

10. A method comprising:
forming a contact etch stop layer over a source/drain by:
depositing a first SiOC layer on the source/drain,
depositing a second SiOC layer on the first SiOC layer,
performing an oxygen treatment on the second SiOC layer, and
depositing a SiN layer on the oxygen-treated, second SiOC layer;
forming an interlayer dielectric layer on the contact etch stop layer; and
forming a source/drain contact to the source/drain, wherein the source/drain contact is formed in the contact etch stop layer and the ILD layer.

11. The method of claim 10, wherein the first SiOC layer and the second SiOC layer are deposited in a same deposition process chamber.

12. The method of claim 10, wherein the first SiOC layer is deposited by a first plasma-enhanced chemical vapor deposition (PECVD), the second SiOC layer is deposited by a second PECVD, and the SiN layer is deposited by atomic layer deposition.

13. The method of claim 10, wherein a deposition temperature each of the depositing the first SiOC layer and the depositing the second SiOC layer is less than about 600° C.

14. The method of claim 10, wherein a deposition time of each of the depositing the first SiOC layer and the depositing the second SiOC layer is less than about one hour.

15. The method of claim 10, wherein the forming the source/drain contact to the source/drain includes completely removing a portion of the SiN layer and partially removing a portion of the second SiOC layer along a sidewall of a gate spacer.

16. The method of claim 10, wherein no oxygen treatment is performed between depositing the first SiOC layer and depositing the second SiOC layer.

17. A device structure comprising:
a gate stack;
a gate spacer disposed along a sidewall of the gate stack;
a source/drain disposed adjacent to the gate spacer;
a source/drain contact structure disposed on the source/drain; and
a contact etch stop layer disposed between the gate spacer and the source/drain contact structure, wherein the contact etch stop layer has a nitrogen-free portion interfacing with the source/drain and the gate spacer.

18. The device structure of claim 17, wherein:
the nitrogen-free portion is a first silicon oxycarbide portion, wherein the first silicon oxycarbide portion has a first oxygen content; and
the contact etch stop layer further has a second silicon oxycarbide portion disposed over the first silicon oxycarbide portion, wherein the second silicon oxycarbide portion has a second oxygen content that is greater than the first oxygen content.

19. The device structure of claim 18, wherein:
the first silicon oxycarbide portion has a first carbon content; and
the second silicon oxycarbide portion has a second carbon content, wherein the second carbon content is less than the first carbon content.

20. The device structure of claim 17, wherein a dielectric constant of the nitrogen-free portion interfacing with the source/drain and the gate spacer is about 3.6 to about 3.7.
